(19) United States
(12) Patent Application Publication
(10) Pub. No.: US 2016/0085655 A1
(43) Pub. Date: Mar. 24, 2016

(54) MONITORING SYSTEM, MONITORING DEVICE, AND MONITORING METHOD

(71) Applicant: KABUSHIKI KAISHA TOSHIBA, Tokyo (JP)

(72) Inventor: Toshio ITO, Kawasaki (JP)

(21) Appl. No.: 14/855,623

(22) Filed: Sep. 16, 2015

(30) Foreign Application Priority Data
Sep. 19, 2014 (JP) 2014-191889

(51) Int. Cl. G06F 11/30; G01R 21/133

(52) U.S. Cl. CPC G06F 11/3065; G06F 11/3055; G06F 11/3068; G01R 21/133

(57) ABSTRACT

According to one embodiment, a monitoring system that monitors a data process using log information includes a first circuitry and a second circuitry. The first circuitry converts a piece of data under a predetermined rule. The second circuitry, when the piece of data is converted by the first circuitry, generates first log information that contains start node identification information, end node identification information and a process executing time point. The start node identification information contains information to identify a piece of data before the conversion. The end node identification information contains information to identify a piece of data after the conversion. The process executing time point is a time point at which the piece of data is converted.

### CROSS-REFERENCE TO RELATED APPLICATIONS

This application is based upon and claims the benefit of priority from Japanese Patent Application No. 2014-191889, filed Sep. 19, 2014; the entire contents of which are incorporated herein by reference.

### FIELD

Embodiments described herein relate to a monitoring system, a monitoring device, and a monitoring method.

### BACKGROUND

Examples of monitoring systems include a system called a building energy management system (BEMS). This is a system that integrally monitors and controls facilities and equipment such as air conditioners and illumination, and sensors such as wattmeters, which are installed inside a building, to achieve stable management and the energy saving of the facilities and equipment. Recent years have seen the development of BEMS services that monitor buildings at remote locations using communication lines, and BEMS services that integrally monitor a plurality of buildings in a lump.

In a remote BEMS service, the measured values of thousands of wattmeters need to be collected and processed, and furthermore, a totalizing process is performed thereon in various units such as buildings, floors, and rooms. The ways of performing these totalizing processes widely differ to suit the convenience of a building or a customer.

In addition, a remote BEMS service generally has a function of collecting and managing the wattmeter data as well as various kinds of data (e.g., of the operating status of facilities and equipment or measured values from thermometers and hygrometers), and the flow of a process for these kinds of data is different from that for the wattmeter data.

An operator of a BEMS performs deadline monitoring to monitor whether a system in the present condition completes a process by a deadline defined in specifications (e.g., whether power consumption data is reflected on a screen), so as to continuously monitor whether the system in the present condition satisfies desired performance. If performance requirements are not satisfied, bottleneck detection is performed to detect a bottleneck spot being a data process that takes a particularly long time. Then, the detected bottleneck spot is subjected to appropriate system reinforcement to improve the system to satisfy the performance requirements.

In a conventional monitoring system, it is required to provide to the monitoring system in advance an execution order relation in the whole data process performed by the monitoring system, which is referred to as an execution flow model. Therefore, if the process details in the monitoring system are changed, the execution flow model must also be changed. For this reason, even a partial change in the execution order relation in the data process requires an operator to expend workload to rewrite the execution flow model.

### BRIEF DESCRIPTION OF THE DRAWINGS

FIG. 1 is a diagram showing an example of a graph drawn by a power consumption visualizing function;

FIG. 2 is a general configuration diagram of a system in a first embodiment;

FIG. 3 is a diagram showing in detail the internal configuration of a remote BEMS 1 in the first embodiment;

FIG. 4 is a flow chart showing a process performed by the remote BEMS 1 in its one cycle;

FIG. 5 is a diagram showing an example of pieces of information saved in a signal master DB 16;

FIG. 6 is a diagram showing an example of a file that is written into a file buffer 112;

FIG. 7 is a diagram showing an example of pieces of information saved in a signal measured value DB 13;

FIG. 8 is a diagram showing an example of information that is saved in a totalization master DB 18 in advance;

FIG. 9 is a diagram showing an example of pieces of information saved in a flow log DB 172;

FIG. 10 is a diagram showing the pieces of information in the flow log DB in FIG. 9 in the form of a graph expression;

FIG. 11 is a diagram showing the configuration of a processor 50 and a monitoring performer 6 in the first embodiment;

FIG. 12 is a table showing processes performed by respective units in respective programs;

FIG. 13 is a flow chart showing an example of the operation by the monitoring performer 6 in the first embodiment;

FIG. 14 is a table showing kinds of data reported from the processor 50 to the monitoring performer 6;

FIG. 15 is a diagram showing the creating rule of a node ID;

FIG. 16 is a diagram showing in detail the configuration of a log analyzer 173;

FIG. 17 is a flow chart showing an example of the process of deadline monitoring;

FIG. 18 is a flow chart showing an example of the process of bottleneck analysis;

FIG. 19 is a diagram showing an example of a calculation result of a stay time in an en-route node;

FIG. 20 is a diagram showing in detail the internal configuration of a remote BEMS 1 in a second embodiment;

FIG. 21 is a diagram showing the configuration of a monitoring performer 6b in the second embodiment;

FIG. 22 is a diagram showing in detail the internal configuration of a remote BEMS 1 in a third embodiment;

FIG. 23 is a diagram showing the configuration of a monitoring performer 6 in the third embodiment;

FIG. 24 is a diagram showing the internal configuration of the remote BEMS 1 in a fourth embodiment;

FIG. 25 is a diagram showing a specific example of kinds of report data in the fourth embodiment;

FIG. 26A is a diagram showing an example of a data flow in the case where a processor 50-1 does not make a transmission report;

FIG. 26B is a diagram showing an example of a data flow in the case where the processor 50-1 makes a transmission report; and

FIG. 27 is a diagram showing the creating rule of a node ID for a transmission event of the processor 50-1 and a reception event of a processor 50-2 in the present embodiment.

### DETAILED DESCRIPTION

According to one embodiment, a monitoring system that monitors a data process using log information includes a first circuitry and a second circuitry.

The first circuitry converts a piece of data under a predetermined rule. The second circuitry, when the piece of data is converted by the first circuitry, generates first log information that contains start node identification information, end node identification information and a process executing time point.

The start node identification information contains information to identify a piece of data before the conversion.

The end node identification information contains information to identify a piece of data after the conversion.

The process executing time point is a time point at which the piece of data is converted.

Below, embodiments will be described with reference to the drawings.

### First Embodiment

First, a first embodiment will be described. A remote BEMS (monitoring system) 1 in the first embodiment has a function of visualizing power consumption, which is one of the typical functions of a BEMS (hereafter, referred to as a power consumption visualizing function). This is a function of collecting, accumulating, and totalizing the measured values of wattmeters in a building, which are summarized into a graph and provided to a user.

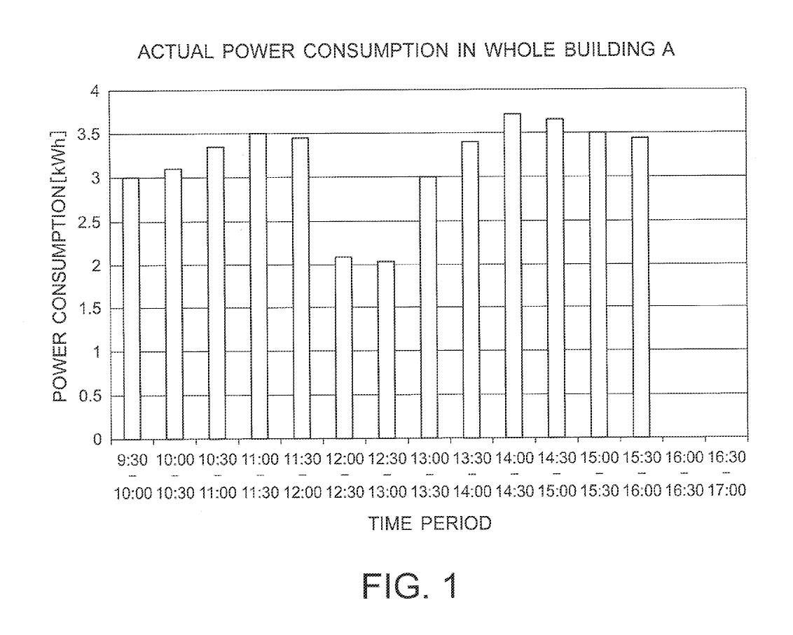

FIG. 1 is a diagram showing an example of a graph drawn by the power consumption visualizing function. This graph shows power consumed in a building as a whole on one day, which is totalized every 30 minutes. Some systems can not only totalize and show the power consumption in a building as a whole, but also totalize and show the power consumption on various bases of such as floor, room, and device type.

The power consumption visualizing function is required to reflect power consumption in a building on a screen in real time. For example, the screen shown in FIG. 1 does not show data from 16:00 to 16:30 because measured values during this time period have not been obtained yet as of browsing the screen. The requirements specification of the visualizing function include, for example, such an item “complete data on this time period is shown by 16:40 (ten minutes after the end of the time period).”

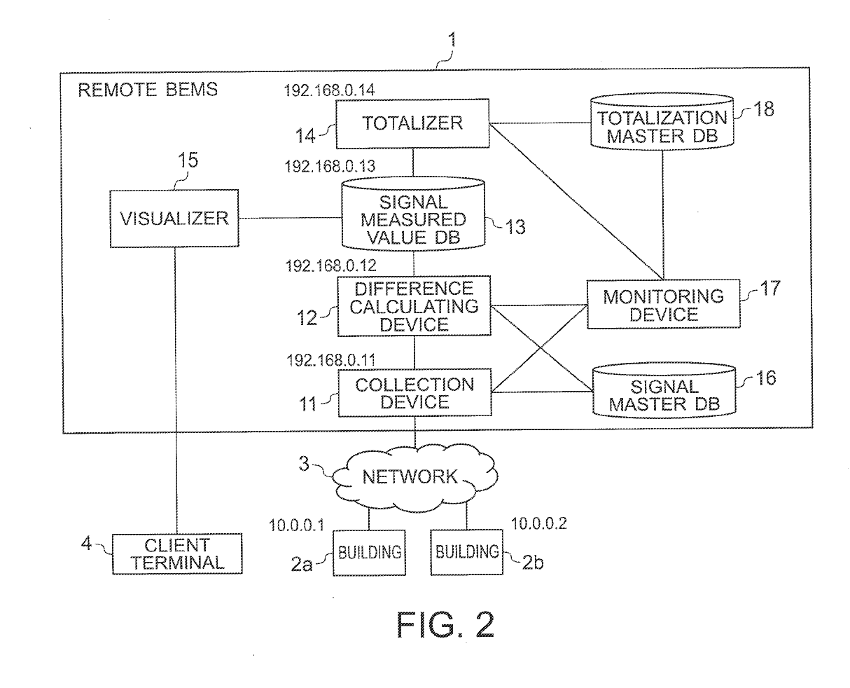

FIG. 2 is a general configuration diagram of a system in the first embodiment. As shown in FIG. 2, the system in the present embodiment includes buildings 2a and 2b a remote BEMS (monitoring system) 1 that monitors them over a network 3, and a client terminal 4 that shows information (e.g., the graph in FIG. 1). The buildings 2a and 2b and the remote BEMS 1 are connected to each other over the network 3.

The remote BEMS 1 includes a collection device 11, a difference calculating device 12, a signal measured value DB (database) 13, a totalizer 14, a visualizer 15, a signal master DB 16, a monitoring device 17, and a totalization master DB 18. In such a manner, the remote BEMS 1 includes a plurality of computers. In the remote BEMS 1, these devices cooperate with one another to provide information on visualized power consumption in the buildings 2a and 2b to the client terminal 4. This causes, for example, the graph shown in FIG. 1 to be shown on the client terminal 4, which allows a user of the client terminal 4 to grasp the power consumption in buildings 2a and 2b. The collection device 11, the difference calculating device 12, the totalizer 14, the visualizer 15 and the monitoring device 17 can be implemented by circuitry such as a processor or an integrated circuit, and further may include a memory or a storage. Each circuitry which implements the collection device 11, the difference calculating device 12, the totalizer 14, the visualizer 15 and the monitoring device 17 may be different physical circuitry or all or a part of them may be same physical circuitry.

The collection device 11 communicates with the buildings 2a and 2b over the network 3 and periodically collects the measured values of wattmeters, operation information of facilities and equipment, the measured values of the other various sensors in the buildings 2a and 2b. These pieces of data handled by the remote BEMS 1 are generally referred to as pieces of “signal data.” In the present embodiment, the collection device 11 communicates with the buildings 2a and 2b with a 30-minute cycle to collect pieces of signal data. The pieces of signal data collected by the collection device 11 are transferred to the difference calculating device 12.

The difference calculating device 12 performs difference computation on pieces of wattmeter data out of the pieces of signal data collected by the collection device 11. This is because the original pieces of wattmeter data each indicate monotonically increasing accumulated power, which is different from the power consumption on a 30-minute basis shown in FIG. 1. The difference calculating device 12 calculates the difference between pieces of wattmeter data obtained by the previous data collection and pieces of wattmeter data obtained this time, and generates the results as new pieces of signal data. Thereafter, the difference calculating device 12 writes the generated pieces of signal data and the collected original pieces of signal data into the signal measured value DB 13.

The signal measured value DB 13 is a database to store the pieces of signal data.

The totalizer 14 performs a totalizing process on the pieces of signal data stored in the signal measured value DB 13. The totalizer 14 sums and totalizes pieces of signal data that belong to a preset totalizing group and writes the resulting pieces of summed signal data into the signal measured value DB. Through this process, thirty-minute-basis power consumption data on each building or floor is generated from the pieces of thirty-minute-basis power consumption data on the individual wattmeters.

The visualizer 15 outputs the information to be shown by the client terminal 4 to the client terminal 4. For example, the visualizer 15 reads out the power consumption data totalized by the totalizer 14 from the signal measured value DB 13, generates image data on the graph shown in FIG. 1 from the read out power consumption data, and outputs this image data to the client terminal 4. This causes the client terminal 4 to display this image data, causing the graph as shown in FIG. 1 to be shown.

The signal master DB 16 is a database to save information on signals that the remote BEMS 1 collects from the buildings 2a and 2b. The collection device 11 and the difference calculating device 12 execute their processes based on data held by the signal master DB 16.

The monitoring device 17 monitors the operation of the remote BEMS 1 to monitor whether totalized power consumption data needed by the visualizer 15 is generated by a deadline. This is referred to as deadline monitoring. In addition, the monitoring device 17 analyzes what process among the processes in the remote BEMS 1 takes the longest time, as needed. This is referred to as bottleneck analysis.

In the totalization master DB 18, information on totalizing groups, for which pieces of signal data are subjected to the totalizing process, is stored.

Each device and building in the system shown in FIG. 2 is allocated a unique IP address. For example, the collection device 11 has an IP address 192.168.0.11, the difference calculating device 12 has 192.168.0.12, the signal measured value DB 13 has 192.168.0.13, and the totalizer 14 has 192.168.0.14. In addition, for example, the building 2a has 10.0.0.1, and the building 2b has 10.0.0.2. Note that the other devices may have IP addresses, but they will be omitted because they are irrelevant to the description of the present embodiment.

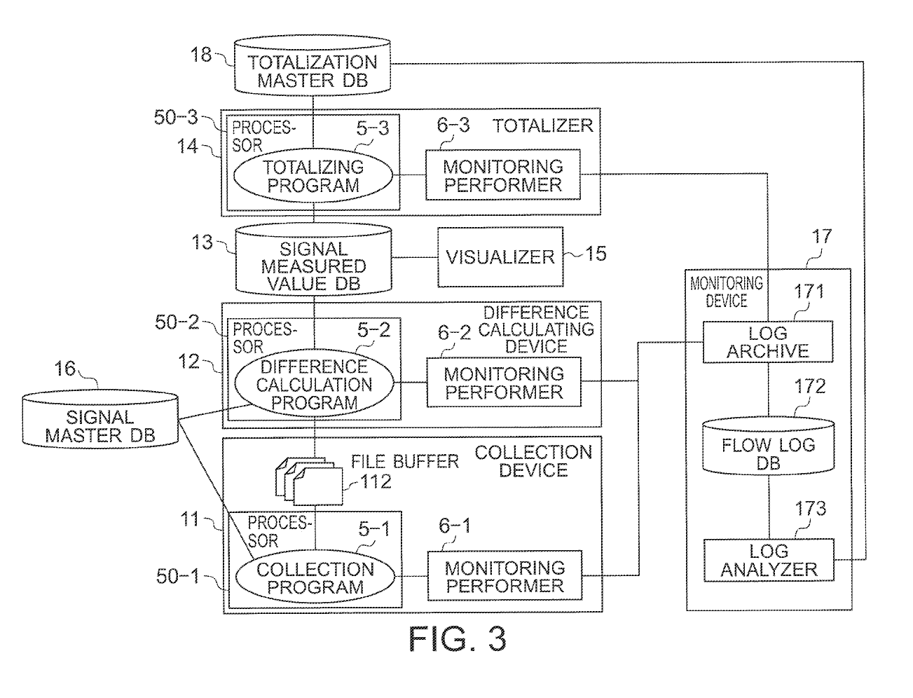

FIG. 3 is a diagram showing in detail the internal configuration of the remote BEMS 1 in the first embodiment. Hereafter, with reference to this drawing, there will be first described the details of a data process relating to the power consumption visualizing function of the remote BEMS 1.

The collection device 11 includes a processor 50-1, a file buffer 112, and a monitoring performer 6-1. The monitoring performer can be implemented by circuitry such as a processor or an integrated circuit, and further may include a memory or a storage.

The processor 50-1 stores therein a collection program 5-1, and executes this collection program 5-1 to collect data. Specifically, the processor 50-1 communicates with the buildings 2a and 2b to collect signal data.

The file buffer 112 is a data buffer area provided on a file system managed by the collection device 11. The collection program 5-1 writes the collected signal data to the file buffer 112 as a file. The file buffer 112 is also accessible from the difference calculating device 12 by a prescribed file sharing function.

The difference calculating device 12 includes a processor 50-2 and a monitoring performer 6-2.

The processor 50-2 stores therein a difference calculation program 5-2, and executes this difference calculation program 5-2 to perform difference calculation on signal data. Specifically, the processor 50-2 reads out the latest piece of signal data from the file buffer 112 reads out the second latest pieces of signal data from the signal measured value DB 13, and calculates the difference between the read out two pieces of signal data, and writes difference signal data obtained through the calculation to the signal measured value DB 13.

The totalizer 14 includes a processor 50-3 and a monitoring performer 6-3.

The processor 50-3 stores therein a totalizing program 5-3, and executes this totalizing program 5-3 to sum and totalize pieces of signal data. Specifically, the processor 50-3 reads out pieces of signal data from the signal measured value DB 13, sums and totalizes them under a totalizing group that is defined in the totalization master DB 18, and writes the resulting summed signal data to the signal measured value DB 13.

The monitoring performers 6-1, 6-2, and 6-3 exist for the respective processors 50-1, 50-2, and 50-3 being objects to be monitored. The monitoring performers 6-1, 6-2, and 6-3 monitor the data processes by the processors 50-1, 50-2, and 50-3, respectively, and transmit, when a specified data process is performed, the information thereon to the monitoring device 17 as pieces of log information.

The monitoring device 17 includes a log archive 171, a flow log DB 172, and a log analyzer 173.

The log archive 171 receives the pieces of log information from the monitoring performers 6-1, 6-2, and 6-3, and saves these received pieces of information in the flow log DB 172. Note that the log archive 171 is not limited to this, but may save at least one of the pieces of log information received from the monitoring performers 6-1, 6-2, and 6-3 in the flow log DB 172.

The flow log DB 172 is a database to save log information.

The log analyzer 173 analyzes the log information saved in the flow log DB 172 and performs the deadline monitoring and the bottleneck analysis.

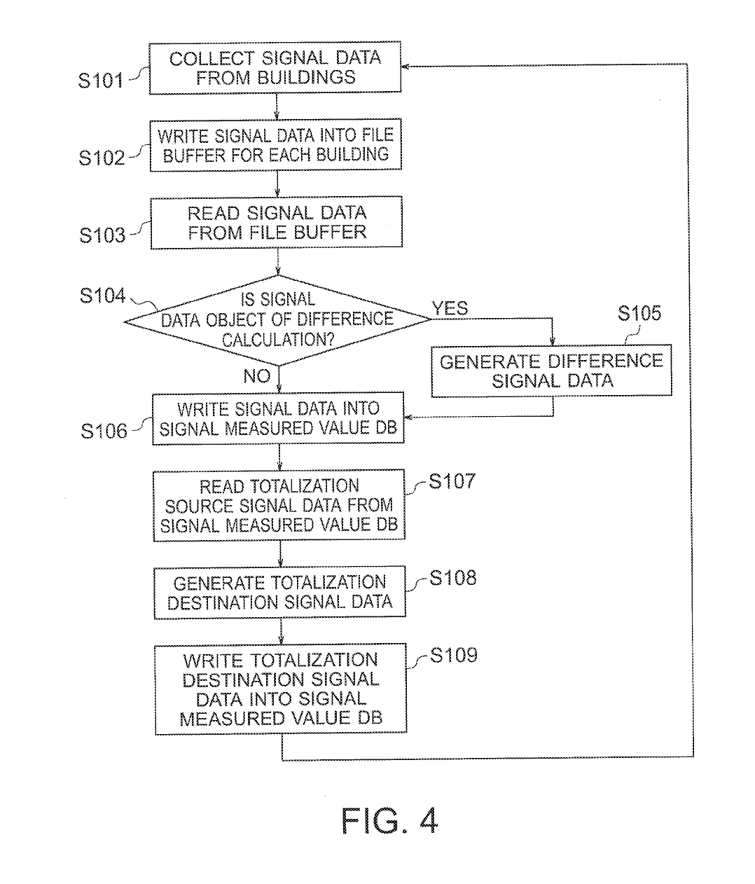

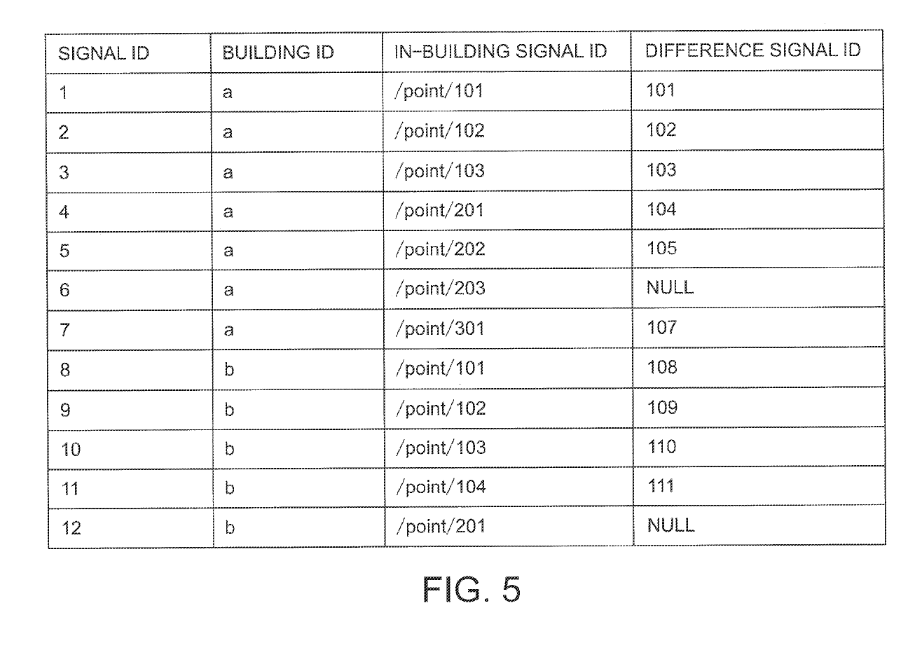

The remote BEMS 1 collects and processes signal data with a 30-minute cycle. Next, there will be described a process that is performed by the remote BEMS 1 in its one cycle with reference to FIG. 4 while referring to FIG. 5 to FIG. 8.

FIG. 4 is a flow chart showing the process performed by the remote BEMS 1 in its one cycle.

(Step S101) First, the remote BEMS 1 starts with collecting signals from the buildings. Specifically, the processor 50-1 refers to the signal master DB 16 (refer to FIG. 5) to acquire a list of signals to be collected, and collects pieces of signal data on the buildings 2a and 2b at that time.

For example, the list of signals to be collected contains all signal IDs included in the signal master DB 16.

Here, FIG. 5 is a diagram showing an example of pieces of information saved in the signal master DB 16. Pieces of signal data managed by the remote BEMS 1 each have a setting of a unique identifier called a signal ID.

In the signal master DB 16, a signal ID to identify a signal to be collected, a building ID to identify a building that holds the signal, an in-building signal ID to identify the signal in the building, and a difference signal ID to identify a difference signal that indicates a difference calculation result between the signal and a signal one cycle before.

Pieces of signal data in the present embodiment are independently managed for each building. Thus, the processor 50-1 transmits an in-building signal ID indicated in the signal master DB 16 to a building to request pieces of signal data. When receiving pieces of signal data from the building, the processor 50-1 adds time stamps to the received pieces of signal data. As this time stamp, a time point at which the processor 50-1 starts the collection in the cycle is uniformly used. In the subsequence processes, the pieces of signal data are managed in the form of the couple of a signal ID and a time stamp.

(Step S102) Next, the processor 50-1 collecting the pieces of signal data from the building writes these pieces of data into the file buffer 112. Here, as a manner of convenience, the processor 50-1 writes the collected pieces of data into files that are different for each building and time stamp.

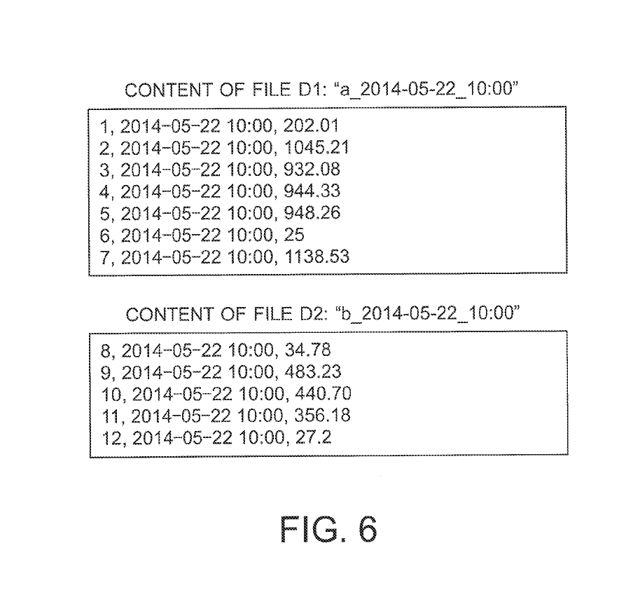

FIG. 6 is a diagram showing an example of a file that is written into the file buffer 112. FIG. 6 shows files D1 and D2 that are output when the data collection is started just at 10 a.m. on May 22, 2014. The file name of the file D1 is “a_{—}2014-05-22_{—}10:00,” and the file name of the file D2 is “b_{—}2014-05-22_{—}10:00”.

This file D1 contains pieces of signal data collected from the building 2a, and the file D2 contains pieces of signal data collected from the building 2b. The files are in a CSV (Comma-Separated Values) format, where each row is a character string including the value of a signal ID, a time stamp, a signal data separated by commas.

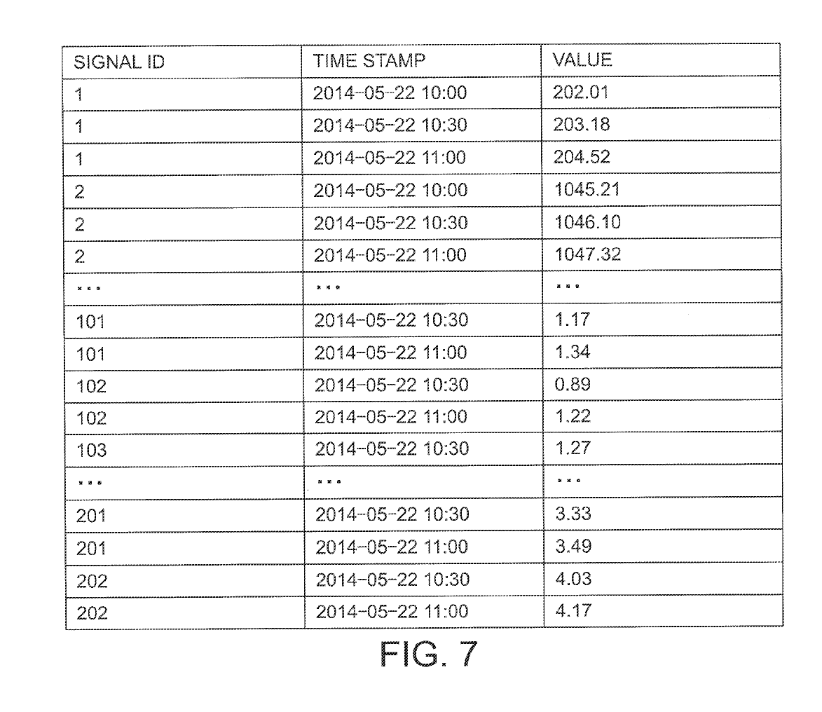

(Step S103) In step S103 in FIG. 4, the processor 50-2 monitors the file buffer 112, and when the processor 50-1 writes pieces of signal data into the file buffer 112, the processor 50-2 reads out these files.
(Step S104) The processor 50-2 performs difference calculation on pieces of wattmeter data among pieces of signal data read out from a file. Wattmeter data is the signal data that have a non-NULL element (here, a number) in the difference signal ID column in the signal master DB 16. The processor 50-2 acquires a difference signal ID corresponding to each piece of read out signal data from the signal master DB 16. At this point, the processor 50-2 determines whether the difference signal ID is not NULL. It is thereby determined whether the piece of signal data is an object of the difference calculation.
(Step S105) If it is judged in step S104 that the difference signal ID is not NULL, the processor 50-2 generates a piece of difference signal data obtained by subtracting a value acquired in the previous collecting from a value acquired this time for this signal, and associates the generated piece of difference signal data with the difference signal ID and stores them in the signal measured value DB. Here, the value acquired in the previous collecting is acquired by extracting “a value” contained in a record having the latest time stamp among records having a signal ID being an object this time, in the signal measured value DB 13. Thereby, as shown in FIG. 7, for example, a record containing a difference signal ID of “101” and a value of difference signal data of “1.17” are added to the signal measured value DB.

FIG. 7 is a diagram showing an example of pieces of information saved in the signal measured value DB 13. The signal measured value DB 13 includes signal IDs, time stamps, and the columns of values, and the values of collected pieces of signal data, pieces of difference signal data obtained through the difference calculation, or pieces of summed signal data obtained through summing and totalizing at each time point are saved therein. Here, in the column of this signal ID, an ID to identify a piece of signal data, a difference signal ID to identify a piece of difference signal data, and an ID to identify a piece of summed signal data are stored.

In addition, the processor 50-2 saves the values collected this time to prepare for the next difference calculation. Note that, as the time stamps of pieces of difference signal data, the time stamps of the pieces of signal data collected this time are used.

(Step S106) Next, when finishing all the difference calculation, the processor 50-2 writes all the collected pieces of signal data and the pieces of difference signal data generated through the difference calculation into the signal measured value DB 13. When all the writing into the signal measured value DB 13 are successfully completed, the processor 50-2 deletes the file in the file buffer 112 that has been read in advance.
(Step S107) Next, the processor 50-3 monitors the signal measured value DB 13, and if there are a plurality of pieces of signal data that can be summed and totalized in the signal measured value DB 13, the processor 50-3 reads them out. The kinds of signal data to be summed and totalized are defined in the totalization master DB 18.

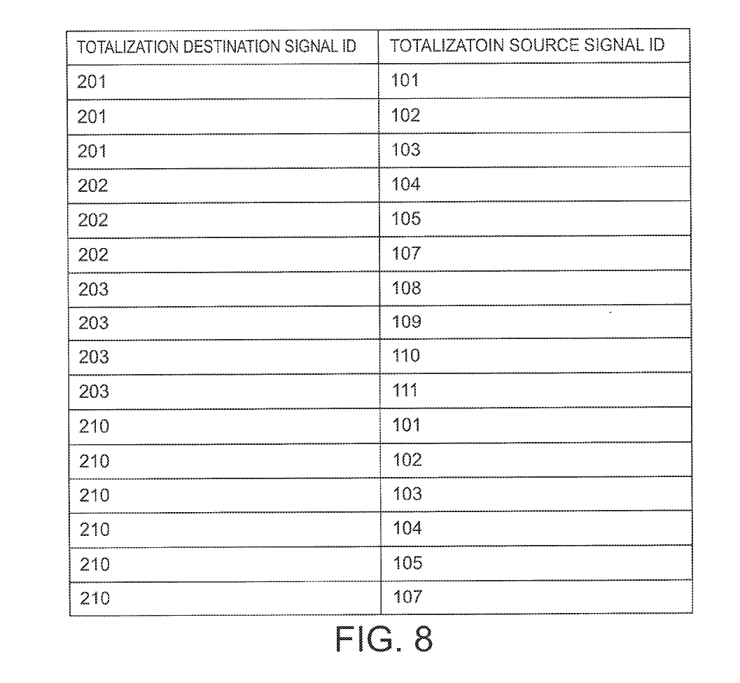

FIG. 8 is a diagram showing an example of information that is saved in the totalization master DB 18 in advance. As shown in FIG. 8, the totalization master DB 18 has the columns of a totalization destination signal ID and a totalization source signal ID.

A set of totalization source signal IDs that have the same totalization destination signal ID forms one totalizing group, and pieces of data corresponding to these totalization source signal IDs are summed to generate a piece of summed signal data.

The processor 50-3 refers to the totalization master DB 18 and read out a plurality of pieces of totalization source signal data that satisfy all the following three conditions from the signal measured value DB 13.

A first condition is that a totalization source signal fully matches one of the totalizing groups defined in the totalization master DB 18. That is, the first condition is that a record having a value in the column of the “signal ID” in the signal measured value DB 13 is identical ID to a value of the column of the “totalization source signal ID” in the totalization master DB 18.

A second condition is that time stamps contained in a plurality of pieces of totalization source signal data to be read out are all identical to one another. That is, the second condition is that the values of the column of the “time stamp” in the signal measured value DB 13 are the same time stamp.

A third condition is that there is no piece of totalization destination signal data having a time stamp identical to the time stamps of the pieces of totalization source signal data, in the signal measured value DB 13. That is, the third condition is that there is no record having a value of the column of the “signal ID” in the signal measured value DB 13 that is a “totalization destination signal ID” associated with the “totalization source signal ID” in the totalization master DB 18, and having a value of the column of the “time stamp” in the signal measured value DB 13 that is identical to a time stamp of a piece of totalization source signal data.

Pieces of signal data satisfying the above conditions are pieces of signal data that can be summed and totalized but have not been summed and totalized yet.

For example, when pieces of data having time stamps being “2014-05-22 10:30” are to be summed and totalized, totalization source signal IDs corresponding to a totalization destination signal ID of “201” are “101,” “102,” and “103,” as shown in FIG. 8, and thus values “1.17,” “0.89,” and “1.27” contained in records, the totalization source signal IDs of which are “101,” “102,” “103” and time stamps of which are “2014-05-22 10:30” are summed. This summing yields a summed value 3.33. Then, the processor 50-3 adds a record, the signal ID of which is “201,” the time stamp of which is “2014-05-22 10:30,” and the value of which is “3.33,” to the signal measured value DB 13.

(Step S108) The processor 50-3 adds up all the values contained in the plurality of read out pieces of signal data to obtain a summed value. The processor 50-3 generates a piece of totalization destination signal data in which the totalization destination signal ID, the time stamp contained in the piece of totalization source signal data read out in step S107, and the obtained summed value are associated with one another.
(Step S109) Then, the processor 50-3 adds the piece of totalization destination signal data generated in step S108 to the signal measured value DB 13.

In the above manner, the remote BEMS 1 collects pieces of data from the wattmeters in the buildings 2a and 2b, calculates 30-minute-basis power consumption, performs the summing process in various totalizing groups such as for each building and floor, and saves the result in the signal measured value DB 13. The visualizer 15 reads out an appropriate piece of totalized signal data from the signal measured value DB 13 in response to a request from the client terminal 4, generates a graph as shown in FIG. 1 from this piece of totalized signal data, and transmits information representing the generated graph to the client terminal 4. This causes the client terminal 4 to display the graph as shown in FIG. 1.

Next, there will be given an explanation of how to monitor the data process in the remote BEMS 1 described above to implement deadline monitoring and bottleneck analysis.

The remote BEMS (monitoring system) 1 in the present embodiment monitors the data process in the remote BEMS (monitoring system) 1, and records a piece of data to generate a graph structure representing the flow of the data process in the flow log DB 172.

Here, the remote BEMS (monitoring system) 1 includes the collection device 11, the difference calculating device 12, the signal measured value DB 13, and a monitoring device 17.

The monitoring performers 6-1, 6-2, and 6-3 transmit pieces of data each representing a data flow edge of one hop that expresses their data processes to the log archive 171 whenever the processors 50-1, 50-2, and 50-3 receive, convert, and transmit data, respectively. Here, the data flow edge is a set of the “start node” and the “end node” of a piece of data, and a “process executing time point.”

The monitoring device 17 includes the log archive 171, the flow log DB 172, and the log analyzer 173.

The log archive 171 causes log information generated by the monitoring performer 6-i to be stored in a storage device, where i is an integer from one to three.

Specifically, for example, the log archive 171 adds the received data flow edge to the flow log DB 172.

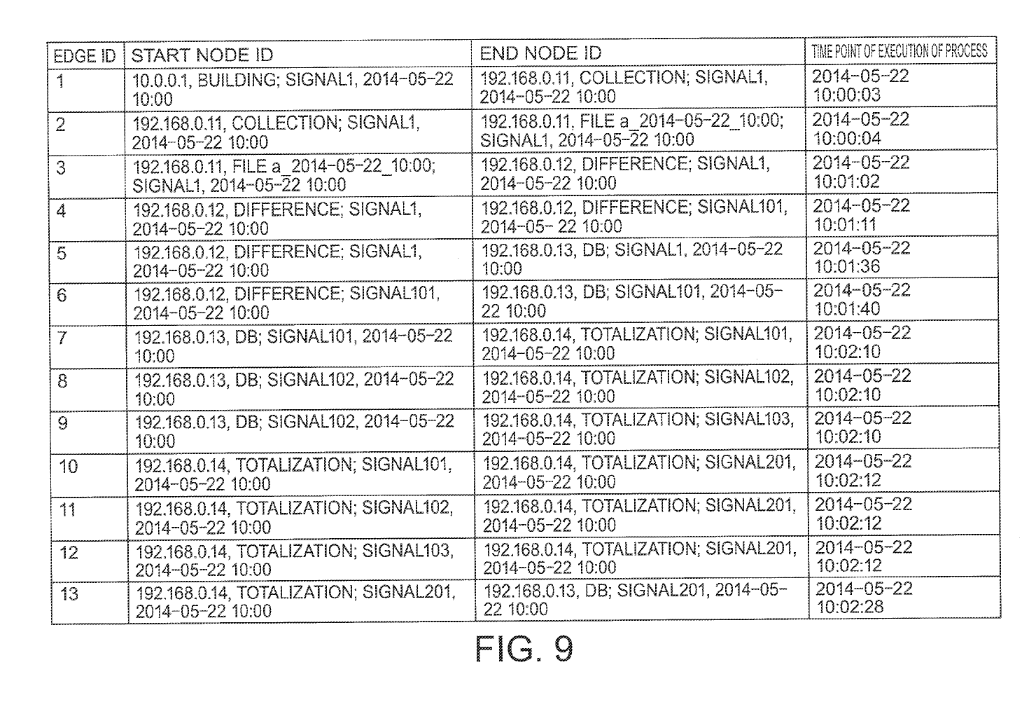

FIG. 9 is a diagram showing an example of pieces of information saved in the flow log DB 172. As shown in FIG. 9, the flow log DB 172 includes the columns of an edge ID to identify an edge that represents a link between nodes, a start node ID to identify a start node, an end node ID to identify an end node, and a process executing time point. The process executing time point is a time point at which its data process is performed. The start node ID and the end node ID contain at least data identifiers to identify pieces of data before and after the data process is performed, respectively.

The start node ID and the end node ID in the present embodiment are in the format of “(device address), (program ID); (signal ID), (time stamp).”

The device address is the IP address of a device that handles data in the event. The program ID is an ID to identify a program executed by a processor that handles data in the device. Here, as an example, the program ID is the name of the program that handles data. The signal ID is an ID of a piece of signal data that is handled in the event, and the time stamp is a time stamp at which the event is performed.

In the above-described node ID format, the former part “(device address), (program ID)” is an ID to identify an entity that handles data, which is called a data handler ID.

In contrast, the latter part “(signal ID), (time stamp)” is an ID to uniquely identify the treated data, which is called a data identifier. A node ID is formed by the combination of a data handler ID and a data identifier.

In each record in the flow log DB 172 shown in FIG. 9, a start node specified by a start node ID and an end node specified by an end node ID are linked to form an edge, which allows the log analyzer 173 to interpret a log recorded in the flow log DB 172 as a graph structure.

Note that in the case of monitoring a system that only converts data using one device, an entity treating data does not need to be identified, and thus a node ID may contain no data handler ID but only a data identifier being the latter part.

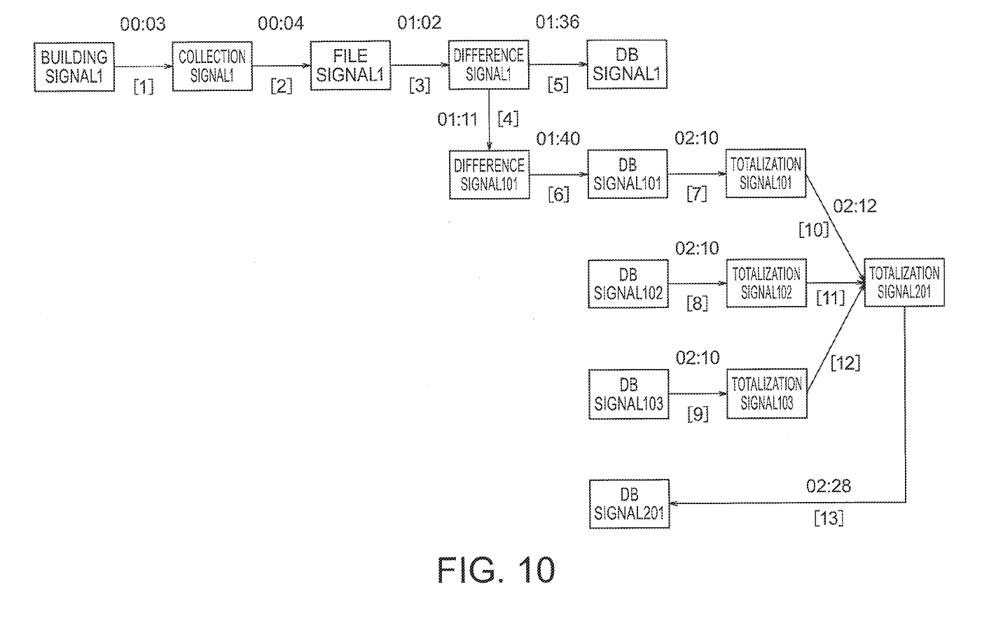

FIG. 10 is a diagram showing the pieces of information in the flow log DB in FIG. 9 in the form of a graph expression. For ease of description, this drawing shows only a program ID and a signal ID as a node ID, and a process executing time point contained in an edge is expressed in the format of “minute:second.” In addition, a number in square brackets is an edge ID.

As shown in FIG. 10, by analyzing the log in the flow log DB 172 in the form of a graph structure, it is possible to learn a process by which a totalized signal (e.g., signal ID is signal 201) is generated. In the case of FIG. 10, the signal ID 201 is generated through the summing and totalizing on the signal IDs 101, 102, and 103, the signal ID 101 is generated through the difference calculation from the signal ID 1, and the signal ID 1 is collected from a building.

Note that although not shown in FIG. 10, it is assumed that the signal IDs 102 and 103 are also generated through the data collection from a building and the difference calculation, as with the signal ID 101, and the record thereof is saved flow log DB 172.

Here, in order to record a log as shown in FIG. 9, it is required for the monitoring performers 6-1, 6-2, and 6-3 to create a data flow edge at an appropriate timing and to transmit it to the log archive 171. This method will be described below.

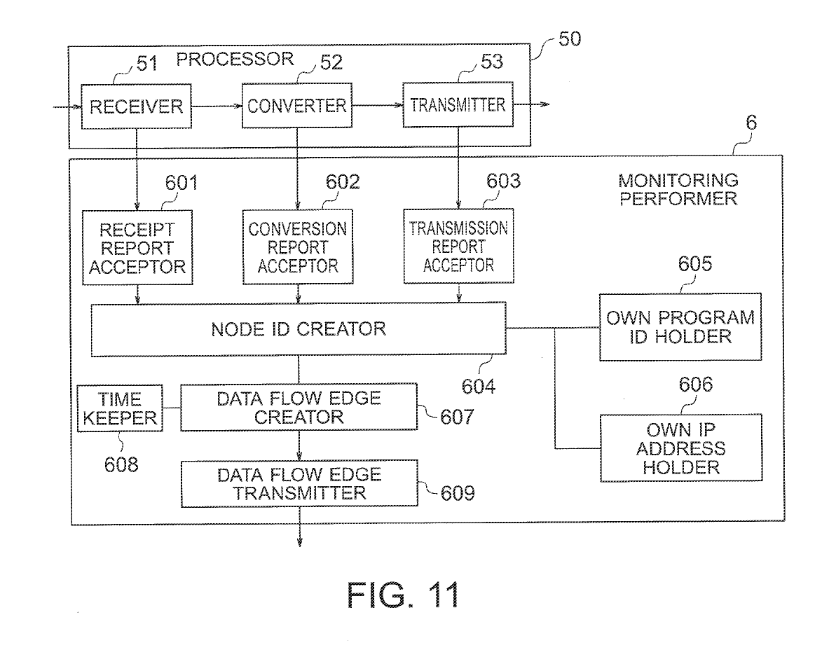

The monitoring performers 6-1, 6-2, and 6-3 monitor the operations of the processors 50-1, 50-2, and 50-3, respectively, and the units have a common structure. The common structure of these processors 50-1, 50-2, and 50-3 and monitoring performers 6-1, 6-2, and 6-3 will be described with reference to FIG. 11. Here, the processors 50-1, 50-2, and 50-3 are collectively referred to as a processor 50. The monitoring performers 6-1, 6-2, and 6-3 are collectively referred to as a monitoring performer 6. The monitoring performer can be implemented by circuitry such as a processor or an integrated circuit, and further may include a memory or a storage. The circuitry may be configured of a circuit, a plurality of circuits or a system of circuits.

FIG. 11 is a diagram showing the configuration of the processor 50 and the monitoring performer 6 in the first embodiment.

As shown in FIG. 11, the processor 50 reads out and executes a program held by itself to function as a receiver 51, a converter 52, and a transmitter 53. The receiver 51 receives data. The converter 52 converts the data received by the receiver 51 under a predetermined rule. Note that the converter 52 not only converts the data received by the receiver 51 but also may convert data held inside a device that includes the converter 52. The transmitter 53 transmits the data converted by the converter 52. Note that the transmitter 53 not only transmits the data converted by the converter 52 but also may transmit the data received by the receiver 51 as it is or may transmit the data held in advance.

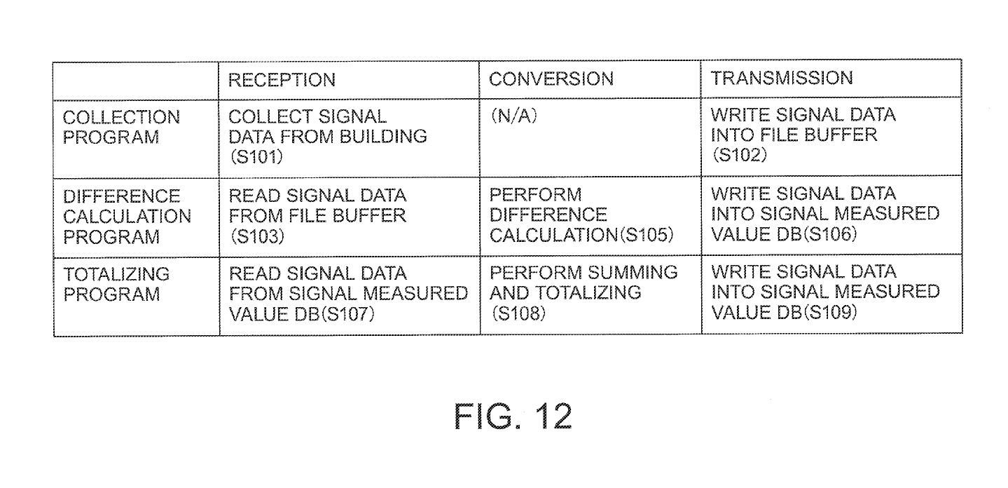

Next, there will be described specific processes performed by the receiver 51, the converter 52, and the transmitter 53 in the respective programs with reference to FIG. 12. FIG. 12 is a table showing processes performed by the respective units in the respective programs. As shown in FIG. 12, the processor 50-1 executing collection program 5-1 does not convert data.

As shown in FIG. 12, in the processor 50-1 executing the collection program 5-1, the receiver 51 collects pieces of signal data from a building, and the transmitter 53 writes the pieces of signal data into the file buffer.

Similarly, in the processor 50-2 executing the difference calculation program 5-2, the receiver 51 reads pieces of signal data from the file buffer, the converter 52 performs the difference calculation, and the transmitter 53 writes pieces of signal data into the signal measured value DB.

Similarly, in the processor 50-3 executing the totalizing program 5-3, the receiver 51 reads pieces of signal data from the signal measured value DB, the converter 52 performs the summing and totalizing, and the transmitter 53 writes a piece of signal data into the signal measured value DB.

The monitoring performer 6 receives a report from the processor 50 and creates a data flow edge. The monitoring performer 6 includes a receipt report acceptor 601, a conversion report acceptor 602, a transmission report acceptor 603, a node ID creator 604, an own program ID holder 605, an own IP address holder 606, a data flow edge creator 607, a time keeper 608, and a data flow edge transmitter 609.

The receipt report acceptor 601 receives a piece of report data that represents a report relating to the operation of the receiver 51 from the receiver 51.

Similarly, the conversion report acceptor 602 receives a piece of report data that represents a report relating to the operation of the converter 52 from the converter 52.

Similarly, the transmission report acceptor 603 receives a piece of report data that represents a report relating to the operation of the transmitter 53 from the transmitter 53.

The own program ID holder 605 holds program IDs to identify the programs 5-1 to 5-3, respectively, for each of the programs 5-1 to 5-3 executed by the processors 50-1 to 50-3 that are monitored by the monitoring performer 6.

The own IP address holder 606 holds the IP addresses of devices in which the monitoring performers 6-1 to 6-3 and the processors 50-1 to 50-3 are installed.

The node ID creator 604 creates the start node ID and the end node ID of a data flow edge, based on the report data received from the receipt report acceptor 601, the conversion report acceptor 602, or the transmission report acceptor 603, and the program IDs held by the own program ID holder 605, and the IP addresses held by the own IP address holder 606.

The time keeper 608 has a time keeping function, and provides information on a current time to the data flow edge creator 607.

The data flow edge creator 607 combines a current time, as information on the process executing time point, with the start node ID and the end node ID received from the node ID creator 604 to create a data flow edge.

The data flow edge transmitter 609 transmits the data flow edge created by the data flow edge creator 607 to the log archive 171.

Note that the monitoring performer 6 can be implemented in, for example, the three forms as shown below. A first form is a form in which the process in the monitoring performer 6 is implemented in the form of a software library and incorporated into the respective programs 5-1, 5-2, and 5-3.

A second form is a form in which the process in the monitoring performer 6 is implemented as a program other than the program 5, and the other program is executed to function as the monitoring performer 6.

In this case, the processor 50 transmits report data to the monitoring performer 6 using a process-to-process communicating mechanism or a shared memory mechanism. Note that the monitoring performer 6 may be made as a resident process or may be started by the processor 50 as needed.

A third form is a form in which the process in the monitoring performer 6 is implemented as a program that runs on a device other than that of the processor 50, and this program is executed by the other device to function as the monitoring performer 6. In this case, the processor 50 transmits report data to the monitoring performer 6 over a network.

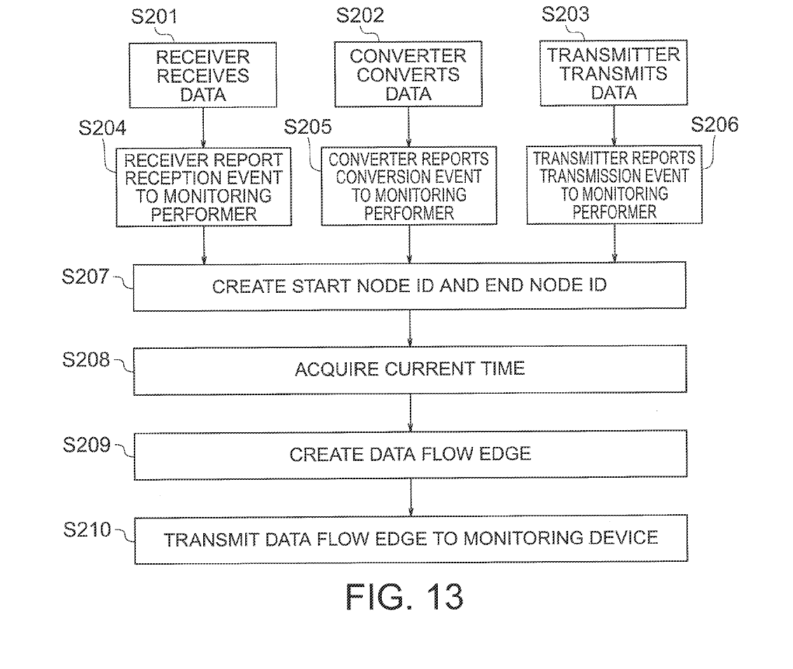

Next, the operation by the monitoring performer 6 will be described with reference to FIG. 13. FIG. 13 is a flow chart showing an example of the operation by the monitoring performer 6 in the first embodiment. The operation by the monitoring performer 6 is started in response to one of the reception, conversion, and transmission of data by the processor 50.

When the receiver 51 of the processor 50 receives data (step S201), the receiver 51 reports the event to the receipt report acceptor 601 (step S204). The reported information is transmitted to the node ID creator 604.

Similarly, when the converter 52 of the processor 50 converts data (step S202), the converter 52 reports the event to the conversion report acceptor 602 (step S205). The reported information is transmitted to the node ID creator 604.

Similarly, when the transmitter 53 of the processor 50 transmits data (step S203), the transmitter 53 reports the event to the transmission report acceptor 603 (step S206). The reported information is transmitted to the node ID creator 604.

The node ID creator 604 creates the start node ID and the end node ID of a data flow edge using the information reported in one of steps S204 to S206, an own program ID, and an own IP address (step S207). The created start node ID and the end node ID are transmitted to the data flow edge creator 607. The data flow edge creator 607 acquires a current time from the time keeper 608 (step S208), and creates a data flow edge using the created start node ID, the end node ID, and the current time (step S209). The created data flow edge is transmitted to the data flow edge transmitter 609. The data flow edge transmitter 609 transmits the data flow edge to the log archive 171 of the monitoring device 17 (step S210).

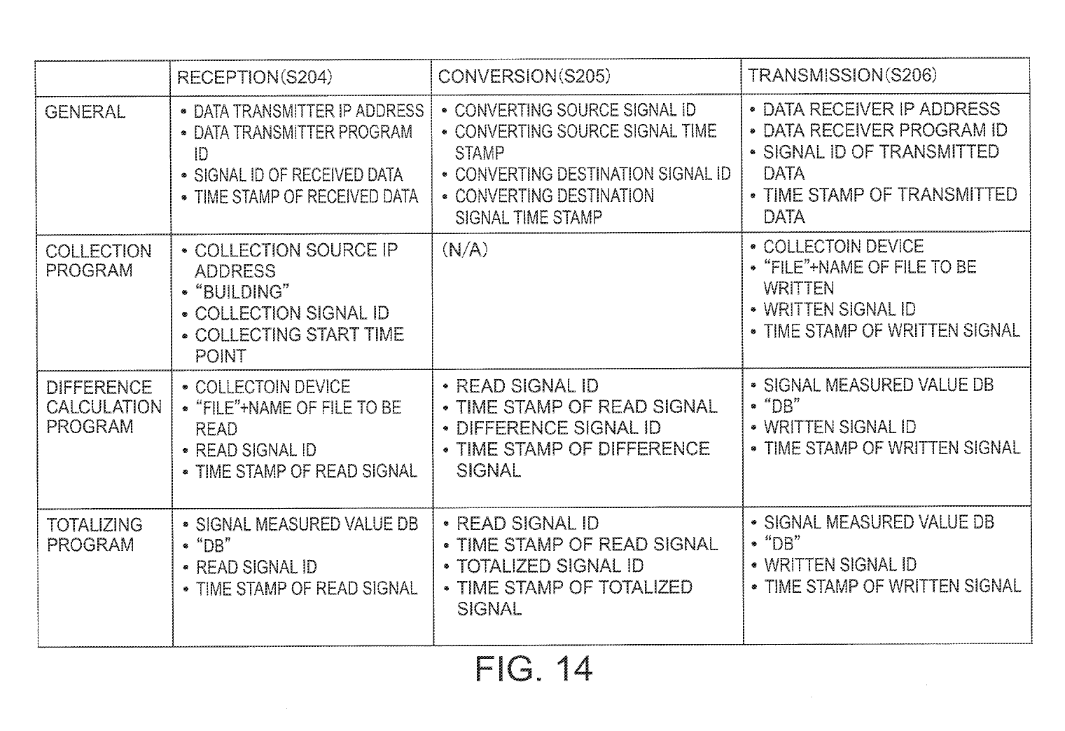

Next, there will be described kinds of data reported from the processor 50 to the monitoring performer 6 in data receiving (step S204 in FIG. 13), in data conversion (step S205 in FIG. 13), and in data transmission (step S206 in FIG. 13) respectively, with reference to FIG. 14. FIG. 14 is a table showing kinds of data reported from the processor 50 to the monitoring performer 6.

As shown in FIG. 14, in data receiving, the IP address and program ID of a data transmitter, and the signal ID and time stamp of a received piece of data are reported. In data conversion, the signal data ID and time stamp of a converting source, and the signal data ID and time stamp of a converting destination are reported. If there are a plurality of pieces of signal data of the converting source and the converting destination, all the combinations thereof are reported. In data transmission, the IP address and program ID of a data receiver, and the signal ID and time stamp of transmitted piece of data are reported.

In addition, FIG. 14 also shows a specific example of what are reported in the reception, conversion, and transmission of data when the collection program 5-1, the difference calculation program 5-2, and the totalizing program 5-3 are executed.

Among the pieces of information reported by each processor 50, a data transmitter IP address and a data receiver IP address are acquired by each processor looking up information on a device to be a communication partner when communication is performed.

The data transmitter program ID and the data receiver program ID are basically held and reported by each processor as character string constants. This is because, in the case of the system in the present embodiment, partners with which each processor exchanges data are almost fixed. However, the case of exchanging signal data with the file buffer 112 is an exception thereto, and in this case, a file name is contained in a program ID. In such a manner, it is possible to specifically check what files the processor 50-1 and the processor 50-2 have accessed, from the records in the flow log DB 172.

As a signal ID and time stamp that are reported in receiving, in the case of the processor 50-1, a signal ID that the processor 50-1 inquiries to the buildings 2a and 2b and a time point at which the processor 50-1 start the collection are used.

Meanwhile, the processor 50-2 reports a signal ID and a time stamp written in a file read from the file buffer 112. Meanwhile, the processor 50-3 reports a signal ID and a time stamp recorded in the signal measured value DB 13. The time stamp here is a time stamp as a portion of a data identifier and different from the “process executing time point” in FIG. 9. The time stamp as a portion of a data identifier is recorded in a file buffer or the signal measured value DB 13 together with a signal ID, and used by the processor 50-2 and the processor 50-3.

Note that the processor 50-3 generates one totalization destination signal for a plurality of totalization source signals in the summing totalizing process, and thus the report of data conversion is made by the number of totalization source signals.

In the above manner, the processors 50-1, 50-2, and 50-3 can report information required by the monitoring performer 6 in each of the events of receiving, converting, and transmitting data. Then, the monitoring performer 6 causes the node ID creator 604 to create a start node ID and an end node ID based on the reported information.

For this reason, when a piece of data is received by the receiver 51, the monitoring performer 6-i, where i is an integer from one to three, generates log information that contains start node identification information (start node ID) containing information to identify a transmission source of the received piece of data, end node identification information (end node ID) containing information to identify an entity receiving the piece of data (e.g., a data handler ID corresponding to the difference calculation program 5-2), and a process executing time point being a time point at which the piece of data is received. Here, in the present embodiment, as an example, the start node identification information (start node ID) and the end node identification information (end node ID) contained in this log information each further contain information to identify the received piece of data.

Then, when the converter 52 converts the piece of data received by the receiver 51, the monitoring performer 6-i generates log information that contains start node identification information (start node ID) containing information to identify a piece of data before the conversion, end node identification information (end node ID) containing information to identify a piece of data after the conversion, and a process executing time point being a time point at which the piece of data is converted.

Here, in the present embodiment, as an example, the start node identification information (start node ID) and the end node identification information contained in this log information further contain information to identify an entity that converts the piece of data (e.g., a data handler ID corresponding to the difference calculation program 5-2).

In addition, when the transmitter 53 transmits the piece of data converted by the converter 52, the monitoring performer 6-i generates log information that contains start node identification information (start node ID) containing information to identify an entity that transmits this piece of data (e.g., a data handler ID corresponding to the difference calculation program 5-2), end node identification information (end node ID) containing information to identify a transmission destination of the transmitted piece of data, and a process executing time point being a time point at which the piece of data is transmitted. Here, in the present embodiment, as an example, the start node identification information and the end node identification information contained in this log information further contain information to identify the transmitted piece of data.

In addition, when the processor 50 receives a piece of data, the monitoring performer 6 acquires data receipt report information from the processor 50 and generates log information whenever this data receipt report information is acquired. Here, the data receipt report information contains information to identify the transmission source of the received piece of data (e.g., the couple of a data transmitter IP address and a data transmitter program ID in FIG. 14), and information to identify this received piece of data (e.g., the couple of the signal ID of a piece of received data and the time stamp of the piece of received data in FIG. 14).

In addition, when the processor 50 converts a piece of data, the monitoring performer 6 acquires data conversion report information from the processor 50 and generates log information whenever this data conversion report information is acquired. Here, the data conversion report information contains information to identify a piece of data before the conversion (e.g., the couple of a converting source signal ID and a converting source signal time stamp in FIG. 14), and information to identify a piece of data after the conversion (e.g., the couple of a converting destination signal ID and a converting destination signal time stamp in FIG. 14).

In addition, when the processor 50 transmits a piece of data, the monitoring performer 6 acquires data transmission report information from the processor 50 and generates third log information whenever this data transmission report information is acquired. Here, the data transmission report information contains information to identify the transmission destination of the transmitted piece of data (e.g., the couple of a data receiver IP address and a data receiver program ID in FIG. 14) and information to identify the transmitted piece of data (e.g., the couple of the signal ID of a piece of transmitted data and the time stamp of the piece of transmitted data in FIG. 14).

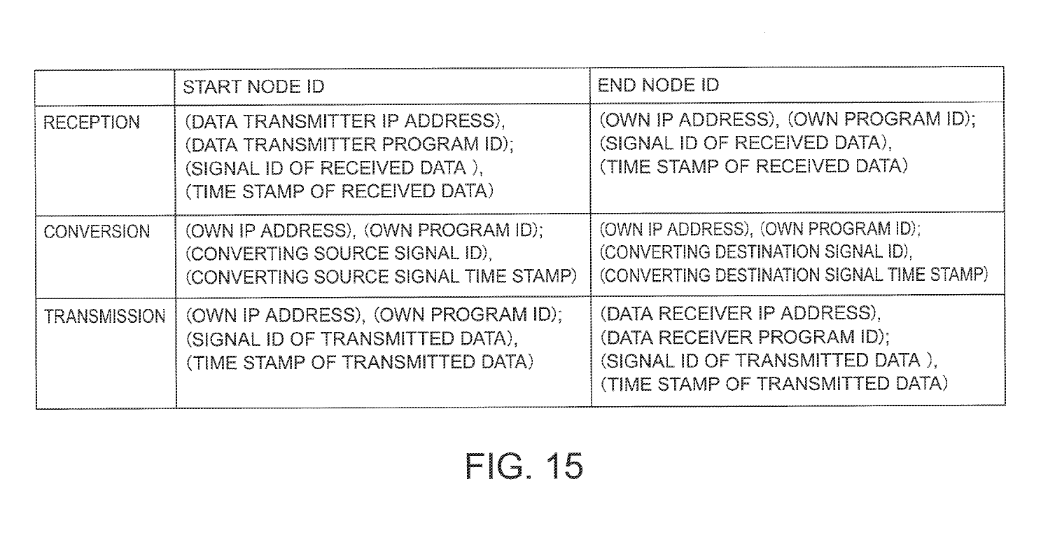

Next, the creating rule of a node ID will be described with reference to FIG. 15. FIG. 15 is a diagram showing the creating rule of a node ID. The node ID creator 604 creates start node IDs and end node IDs corresponding to the respective events of the reception, conversion, and transmission of data according to the creating rule shown in FIG. 15.

At the time of creating a node ID, a starting point and an ending point have a common data ID part in receiving and transmitting data, and a starting point and an ending point have a common data handler ID part in converting data. In such a manner, it is possible to reliably record and track a complex data flow.

In such a manner, when the process in the processor 50 is to transmit a piece of data, the monitoring performer 6 generates log information whenever the processor 50 transmits a piece of data. First identification information at this point (here, a start node ID) contains a data transmitting entity identifier to identify an entity that transmits this piece of data (the couple of the own IP address and the own program ID in FIG. 15) and a data identifier to identify this piece of data (the couple of the signal ID of a piece of transmitted data and a time stamp of the piece of transmitted data in FIG. 15). In addition, second identification information at this point (here, an end node ID) contains a data receiving entity identifier to identify an entity that receives a piece of data (e.g., the couple of the data receiver IP address and the data receiver program ID in FIG. 15) and data identifier to identify the piece of data (e.g., the couple of the signal ID of a piece of transmitted data and the time stamp of the piece of transmitted data in FIG. 15).

In addition, when the process in the processor 50 is to receive a piece of data, the monitoring performer 6 generates log information whenever the processor 50 receives a piece of data. The first identification information at this point (here, a start node ID) contains a data transmitting entity identifier to identify an entity that transmits this piece of data (e.g., the couple of the data transmitter IP address and the data transmitter program ID in FIG. 15) and data identifier to identify this piece of data (e.g., the couple of the signal ID of a piece of received data and the time stamp of the piece of received data in FIG. 15). In addition, the second identification information at this point (here, an end node ID) contains data receiving entity identifier to identify an entity that receives this piece of data (e.g., the couple of the own IP address and the own program ID in FIG. 15) and data identifier to identify this piece of data (e.g., the couple of the signal ID of a piece of received data and the time stamp of the piece of received data in FIG. 15).

In addition, when the process in the processor 50 is to convert data, the monitoring performer 6 generates log information whenever the processor 50 converts data. The first identification information at this point (here, a start node ID) contains a data converting entity identifier to identify an entity that converts this piece of data (e.g., the couple of the own IP address and the own program ID in FIG. 15) and data identifier to identify a piece of data before the conversion (e.g., the couple of the converting source signal ID and the converting source signal time stamp in FIG. 15). In addition, the second identification information at this point (here, an end node ID) contains a data converting entity identifier to identify an entity that converts this piece of data (e.g., the couple of the own IP address and the own program ID in FIG. 15) and a data identifier to identify a piece of data after the conversion (e.g., the couple of the converting destination signal ID and the converting destination signal time stamp in FIG. 15).

By the operation of the monitoring performer 6 described above, a data flow edge is created in accordance with the operation of the remote BEMS 1 and transmitted to the log archive 171 of the monitoring device 17. The data flow edge is stored in the flow log DB 172, and a log shown in FIG. 9 is recorded.

Next, there will be described a method of analyzing a log recorded in the flow log DB 172 by the scheme that has been described thus far to perform the deadline monitoring and the bottleneck analysis.

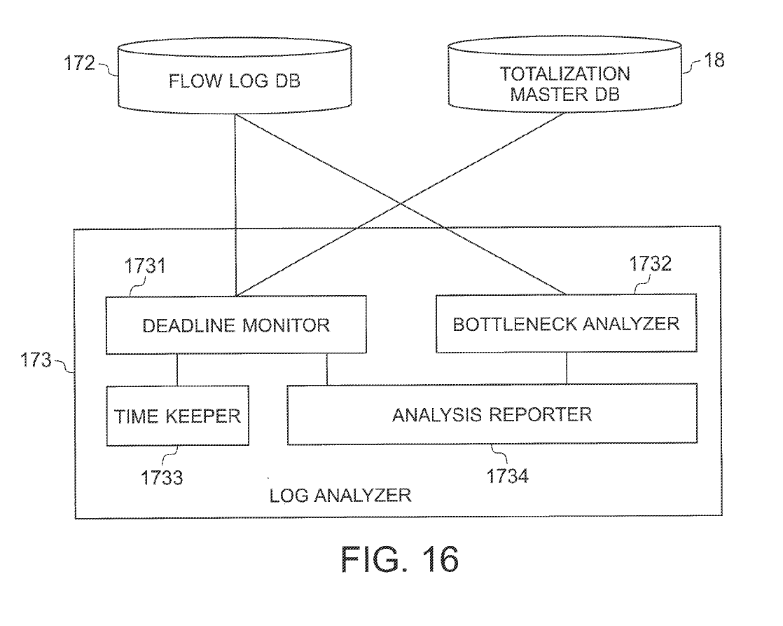

FIG. 16 is a diagram showing in detail the configuration of the log analyzer 173. As shown in FIG. 16, the log analyzer 173 includes a deadline monitor 1731, a bottleneck analyzer 1732, a time keeper 1733, and an analysis reporter (reporter) 1734. The deadline monitor 1731 and the bottleneck analyzer 1732 are connected to the flow log DB 172 and the totalization master DB 18. The log analyzer 173, the deadline monitor 1731, the bottleneck analyzer 1732, a time keeper 1733, and the analysis reporter (reporter) 1734 can be implemented by circuitry such as a processor or an integrated circuit, and further may include a memory or a storage. The circuitry may be configured of a circuit, a plurality of circuits or a system of circuits. Each circuitry which implements the log analyzer 173, the deadline monitor 1731, the bottleneck analyzer 1732, a time keeper 1733, and the analysis reporter (reporter) 1734 may be different physical circuitry or all or a part of them may be same physical circuitry.

When a current time reaches a predetermined deadline time point, for each piece of completion needed data the process of which needs to be completed by the deadline time point, the deadline monitor 1731 determines whether second identification information (here, an end node ID) contains information to identify the data, and log information the process executing time point of which is a time point before the deadline time point is stored in the flow log DB 172 being a storage device.

If the deadline monitor 1731 determines, for at least one of the pieces of completion needed data, that log information the end node identification information (end node ID) of which contains information to identify the piece of data and the process executing time point of which is a time point before the deadline time point is not stored in the flow log DB 172 being a storage device, the analysis reporter 1734 performs a process of notifying a deadline violation.

For a couple of end node identification information (end node ID) contained in an object piece of log information and start node identification information (start node ID) contained in the other piece of log information that are the same among a set of pieces of log information stored in the flow log DB 172 being a storage device, the bottleneck analyzer 1732 calculates the difference between a process executing time point contained in the object log information and a process executing time point contained in the other log information as a stay time of a piece of data that is identified by the end node identification information (end node ID) or the start node identification information (start node ID), and identifies a data process being a bottleneck using the stay time.

In addition, the analysis reporter 1734 performs a process of notifying the process being a bottleneck that is identified by the bottleneck analyzer 1732.

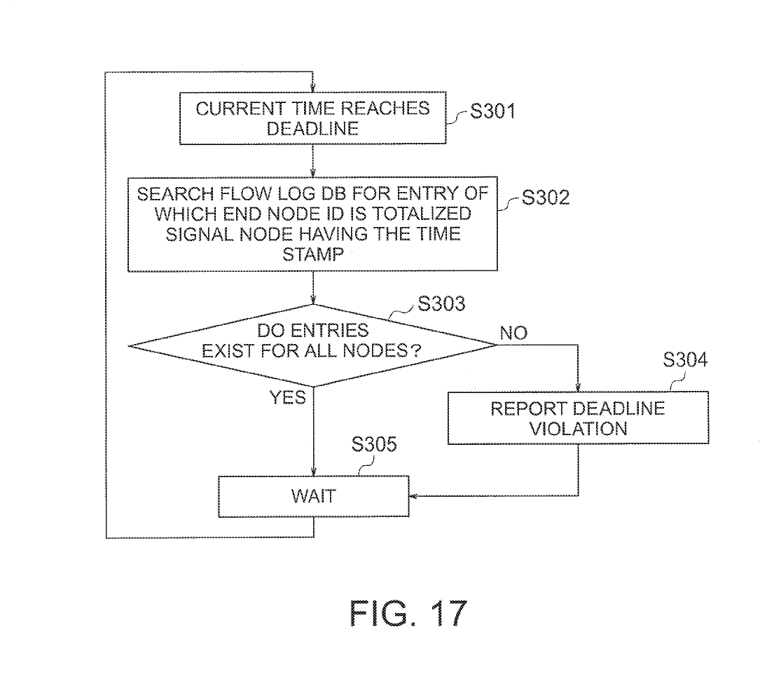

Next, the operation of the deadline monitor 1731 will be described with reference to FIG. 17. FIG. 17 is a flow chart showing an example of the process of deadline monitoring. The remote BEMS 1 in the present embodiment performs the collection and totalization of pieces of data at a 30-minute cycle, and thus the deadline monitor 1731 operates every 30 minutes. Here, it is assumed that pieces of totalized power consumption data must be generated by five minutes after the start of collecting pieces of signal data. That is, if collecting start time points of the pieces of signal data are 10:00, 10:30, 11:00, . . . , the deadlines thereof are 10:05, 10:35, 11:05, . . . , respectively.

(Step S301) The operation in the deadline monitoring is started in response to the deadline monitor 1731 detecting that a current time reaches the next deadline. Here, it is assumed that the current time is 2014-05-22 10:05.
(Step S302) When the current time reaches the deadline, the deadline monitor 1731 searches the flow log DB 172 for an entry the end node ID of which is an ID to identify a totalized signal node having a time stamp being an object to be monitored.

Here, assuming that the current time is 10:05, a time stamp being an object to be monitored is 10:00. In addition, the distinct set of the totalization destination signal ID column is extracted from the totalization master DB 18 as the list of the signal IDs of totalized signals. In the example of FIG. 8, the list of the totalized signal nodes is “201, 202, 203, and 210.”

Specifically, the deadline monitor 1731 searches for a totalized signal node in the flow log DB 172 as a node having an end node ID of “192.168.0.13, DB; (totalization destination signal ID), 2014-05-22 10:00.”

Here, the deadline monitor 1731 can obtain the list of node IDs the deadlines of which have to be checked this time by applying totalization destination signal IDs obtained from the totalization master DB 18 to the above part of (totalization destination signal ID). In the example of FIG. 8, “the (totalization destination signal ID)” is any value included in “201, 202, 203, and 210.”

The above node is a node indicating that a piece of totalized signal data exists in the signal measured value DB 13. Thus, the deadline monitor 1731 searches the above flow log DB 172 for an entry having the node IDs contained in the above list of node IDs as an end node ID (refer to FIG. 9).

(Step S303) Then, the deadline monitor 1731 judges whether entries exist in the flow log DB 172 for all the searched node IDs.
(Step S304) If there is any node ID among the node IDs searched in step S303 for which no entry exists in the flow log DB 172, the deadline monitor 1731 notifies the analysis reporter 1734 of the occurrence of a deadline violation. At this point, the analysis reporter 1734 is notified of information on a signal ID at which the deadline violation occurs, and the like.

The analysis reporter 1734 reports the occurrence of the deadline violation to an administrator of the remote BEMS 1 based on the information received from the deadline monitor 1731. This can be implemented using methods such as sending e-mails, display on a screen in a monitoring center, and warning or switching on a flasher.

(Step S305) If it is judged that entries exist in the flow log DB 172 for all the node IDs searched in step S303, which means that all the pieces of totalized signal data have been generated by the deadline, the deadline monitor 1731 reports nothing and waits for the next deadline.

Note that, the above searching process of the flow log DB 172 (step S302) and the existence checking process of entries (step S303) essentially judge whether compound condition, in which “a node having a given node ID exists in the flow log DB 172 and an input edge exists for the node,” is satisfied. This judgment may be made in one searching process as described above, or may be made step by step. That is, there may be a method in which the deadline monitor 1731 first checks whether a given node ID is included in the flow log DB 172 as a start node ID or an end node ID, and if the given node ID is included, the deadline monitor 1731 checks whether an input edge exists for the node.

As described above, the deadline monitor 1731 can perform the deadline monitoring by searching the flow log DB 172 for an entry containing a totalization destination signal ID as an end node ID to examine whether a desired piece of data exists at some point in time.

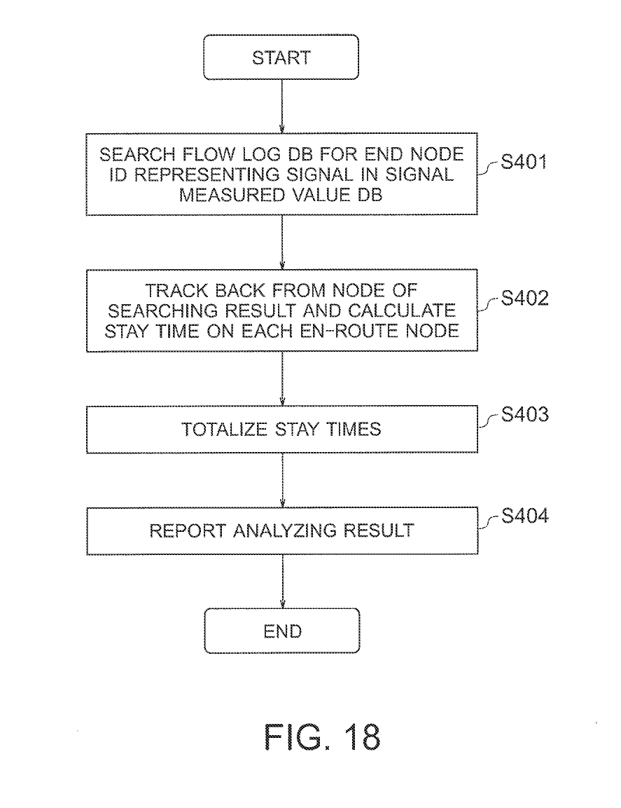

Next, the operation of the bottleneck analyzer 1732 will be described with reference to FIG. 18. FIG. 18 is a flow chart showing an example of the process of the bottleneck analysis. The bottleneck analysis may be performed with any timing. The bottleneck analysis is performed at timing such as once a day as a batch process, by explicit instructions from an administrator of the remote BEMS, and in response to a deadline violation.

(Step S401) When the bottleneck analysis is started, the bottleneck analyzer 1732 first searches, as an example, the flow log DB 172 for an end node ID representing a signal in the signal measured value DB 13. This may be performed by searching the flow log DB 172 for an entry having an end node ID of “192.168.0.13, DB; (*).” However, in the above node ID, “(*)” denotes a wildcard that expresses any character string. A node obtained by this search is called a searching result node.

Note that operating the system for a long term makes a great number of nodes matching the above pattern. For this reason, an upper limit may be imposed on the number of nodes at the time of searching for nodes. In addition, a range of signal IDs or process executing time points to be searched may be specified. In addition, information indicating whether the bottleneck analysis has been performed is held for each signal ID and time stamp, and only nodes corresponding to unanalyzed pieces of signal data may be searched for.

(Step S402) Next, for each node resulting from the search of the flow log DB 172, the bottleneck analyzer 1732 finds nodes on a route to the node by tracking an edge in a reverse direction. These nodes are called en-route nodes.
(Step S403) Then, for each en-route node, a time taken to perform the process in the system on the en-route node is calculated. This taken time is called a stay time in an en-route node.

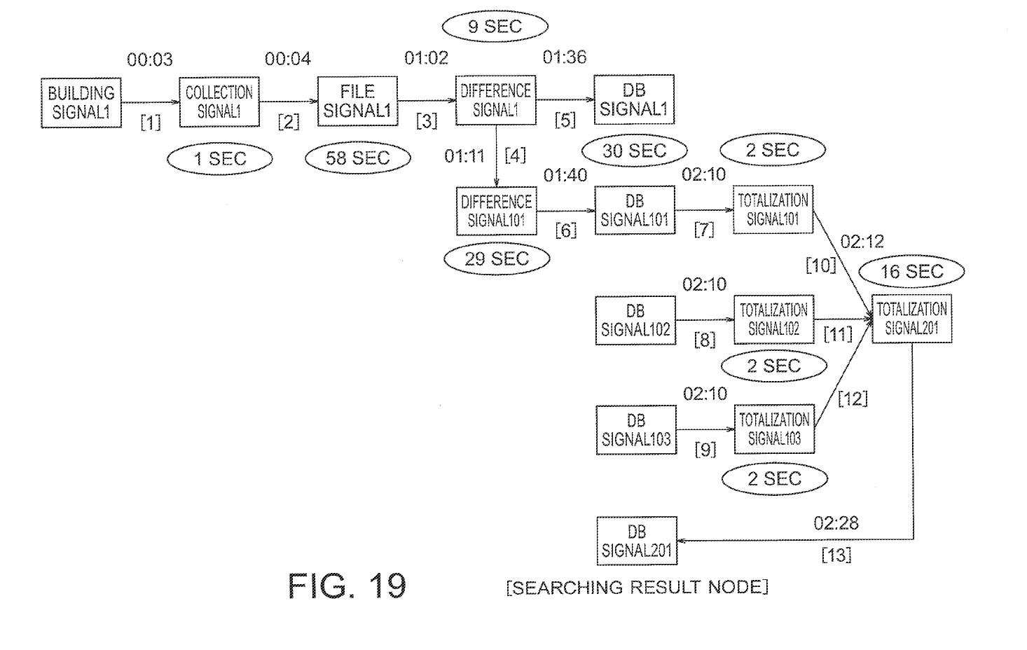

FIG. 19 is a diagram showing an example of a calculation result of a stay time in an en-route node. This drawing is the calculation of the stay time assuming that a node ID of “192.168.0.13, DB; signal 201, 2014-05-22 10:00” is obtained through the search of the flow log DB 172 in the example of FIG. 10.

FIG. 19 shows a searching result node denoted by “DB, signal 201” and en-route nodes obtained by tracing edges in a reverse direction. In this example, all the nodes except for a node “DB, signal 1” are en-route nodes.

The stay times in the en-route nodes are shown by the numbers of seconds in ovals. Here, the stay time of the en-route nodes are each calculated by stay time=(the process executing time point of the output edge of a node in question)−(the process executing time point of the input edge of the node in question).

Note if the node in question has a plurality of output edges, the bottleneck analyzer 1732 makes, for example, an edge used to find en-route nodes an edge to be used to calculate a stay time. If the node in question has a plurality of input edges, the bottleneck analyzer 1732 may use the minimum value, the maximum value, the median, or the other appropriate representative values of these process executing time points as the “process executing time point of the input edge of the node in question,” or may nondeterministically calculate a plurality of stay times.

(Step S404) When the calculation of the stay times is completed in the above manner, the bottleneck analyzer 1732 next totalizes these stay times. There are various methods for this.

Totalizing methods of stay times include one in which en-route nodes are grouped and stay times are totalized for each group. Grouping nodes in the flow log DB 172 for each data handler ID (the first half portion of a node ID) allows the nodes to be grouped on a per device basis, or on a per program basis. By totalizing stay times that are calculated for all the searching result nodes and the en-route nodes for each of the above groups, it is possible to obtain knowledge such as the average values, minimum values, maximum values, and variances of processing times of the programs. Through this analysis, the bottleneck analyzer 1732 can identify a program taking an especially long processing time as a bottleneck.

Another totalizing method of a stay time is a method of finding an en-route node having the longest stay time for each searching result node. In the case of FIG. 19, the stay time of a node “file, signal 1” is the longest, and this can be considered to be a bottleneck. In such a manner, the bottleneck analyzer 1732 finds an en-route node having the longest stay time for each searching result node. Thereafter, the number of times the stay time becomes the longest is totalized for each of the above-mentioned groups. If there is a group having an especially large number of times the stay time becomes the longest, the process of the group is a bottleneck of the system. In such a manner, the bottleneck analyzer 1732 may totalize the number of times the stay time becomes the longest for each group and identify the process of a group being a bottleneck in accordance with the totalized number.

When the totalization of the stay times is completed, The bottleneck analyzer 1732 passes this totalizing result to the analysis reporter 1734, and the analysis reporter 1734 reports this totalizing result to an administrator of the remote BEMS. Here, the totalizing result may contain information on the identified process being a bottleneck. In addition, as means for reporting, means similar to that in the case of the deadline monitoring (refer to step S304 in FIG. 17) can be used.

As described above, the remote BEMS (monitoring system) 1 in the first embodiment is a system that monitors a data process using log information, and includes the receiver 51 receiving a piece of data, the converter 52 converting the piece of data received by the receiver 51, and the monitoring performer 6.

When the converter 52 converts a piece of data received by the receiver 51, the monitoring performer 6 generates log information that contains start node identification information containing information to identify a piece of data before the conversion, end node identification information containing information to identify a piece of data after the conversion, and a process executing time point being a time point at which the piece of data is converted. The log archive 171 causes this log information to be stored in the flow log DB 172 being a storage device. In addition, when the receiver 51 receives a piece of data, the monitoring performer 6 generates log information that contains start node identification information containing information to identify the transmission source of the received piece of data, end node identification information containing information to identify an entity that receives this piece of data, a process executing time point being a time point at which the piece of data is received. Then, the log archive 171 causes this log information to be stored in the flow log DB 172 being a storage device.

In addition, the remote BEMS (monitoring system) 1 further includes the transmitter 53 transmitting a piece of data converted by the converter 52. Then, when the transmitter 53 transmits a piece of data converted by the converter 52, the monitoring performer 6 generates log information that contains start node identification information containing information to identify an entity transmitting this piece of data, end node identification information containing information to identify the transmission destination of the transmitted piece of data, and a process executing time point being a time point at which the piece of data is transmitted. Then, the log archive 171 causes this log information to be stored in the flow log DB 172 being a storage device.

The monitoring performer 6 in the present embodiment thereby generates pieces of log information for the respective individual data processes such as the reception, conversion, and transmission of data, and the log archive 171 accumulates the generated pieces of log information one by one in the flow log DB 172. For this reason, whenever two pieces of log information are detected from these pieces of stored log information, the two pieces of log information including an object piece of log information containing a start node ID and the other piece of log information containing an end node ID, the a start node ID and end node ID being the same, the object piece of log information as an input side is connected to the other piece of log information as an output side. It is thereby possible to express the flow of a data process in the form of a graph structure. As a result, it is possible to monitor the flow of the data process.

In addition, even when the execution order relation in the data process is changed, the monitoring performer 6 in the present embodiment can generate pieces of log information as before the change without changing the configuration or the setting and can express the flow of the changed process in the form of a graph structure by accumulating the pieces of log information in the flow log DB 172. For this reason, there is no need of changing the remote BEMS (monitoring system) 1 with human intervention when the execution order relation of the data process is changed, and thus, even when the execution order relation of the data process is changed, it is possible to continue to monitor the data process with a little workload.

In addition, even in the cases where the flow of the data process is complex and fluid, the remote BEMS (monitoring system) 1 in the present embodiment can generate pieces of log information based on the respective flows and can always provide analysis that correctly reflects the present circumstances.

Furthermore, since a piece of log information contains a process executing time point, it is possible to perform the deadline monitoring and the bottleneck analysis by analyzing a graph structure and process executing time points in combination.

### Second Embodiment

Next, a second embodiment will be described. In the first embodiment, the monitoring performer 6 exists in each processor 50-i being an object to be monitored. In contrast thereto, in the second embodiment, one monitoring performer 6b monitors a plurality of processors 50.

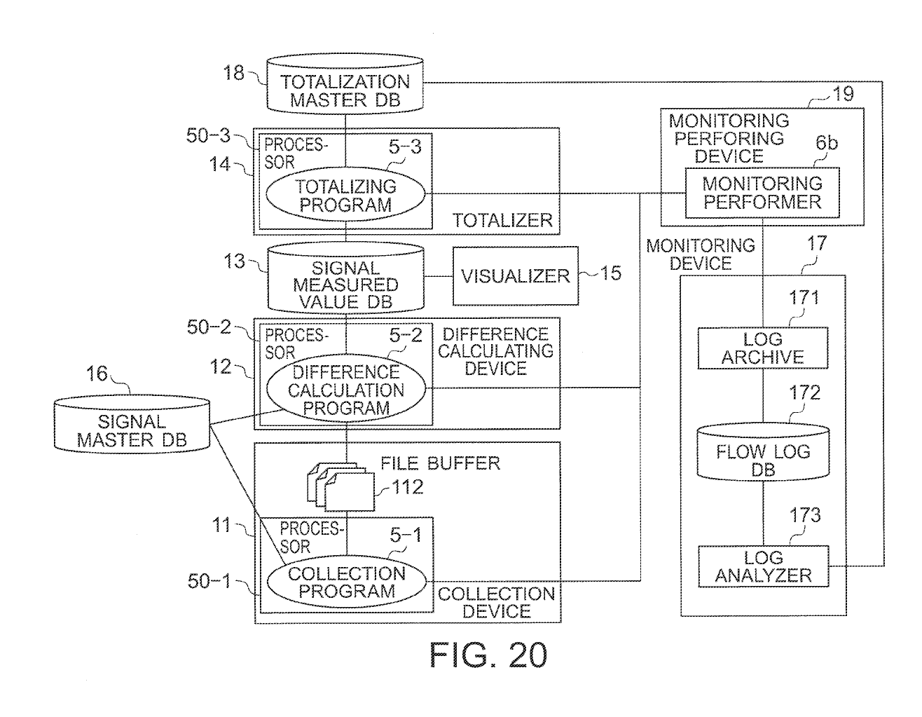

FIG. 20 is a diagram showing in detail the internal configuration of a remote BEMS 1 in the second embodiment.

As shown in FIG. 20, the configuration of the remote BEMS 1 in the second embodiment is almost the same as the detailed configuration of the remote BEMS 1 in the first embodiment shown in FIG. 3 except that the monitoring performer 6b is located in an independent monitoring performing device 19 and monitors all the processors 50-1, 50-2, and 50-3. Note that the monitoring performing device 19 may be formed as a device integrated with the other device (e.g., the monitoring device 17).

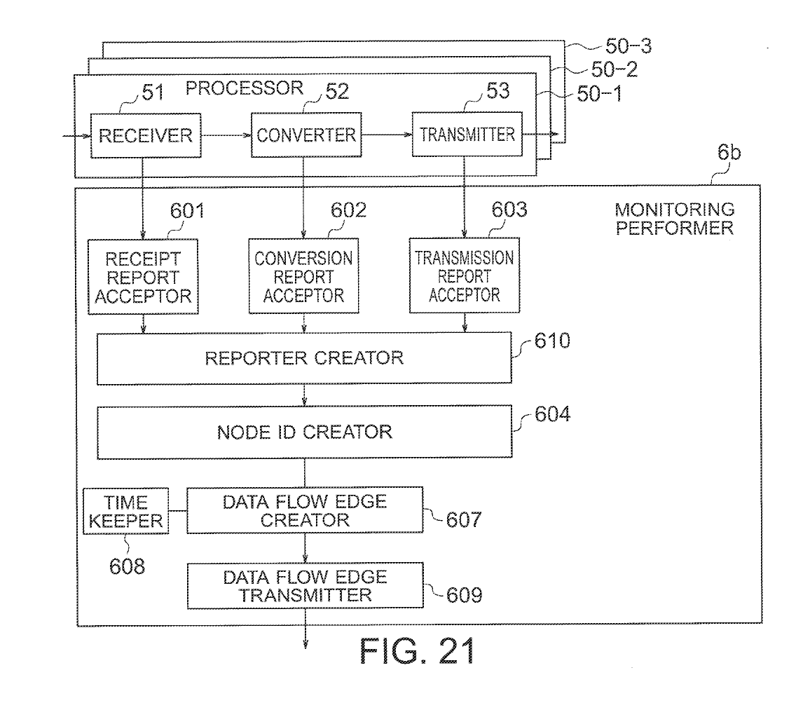

FIG. 21 is a diagram showing the configuration of the monitoring performer 6b in the second embodiment. The configuration of the monitoring performer 6b in the second embodiment is almost the same as the configuration of the monitoring performer 6 in the first embodiment shown in FIG. 11 except that the own program ID holder 605 and the own IP address holder 606 are eliminated, and a reporter creator 610 is added.

In the first embodiment, the node ID creator 604 determines the start node ID and the end node ID of a data flow edge under the rule shown in FIG. 15. However, the monitoring performer 6b in the present embodiment monitors the operations of a plurality of programs and cannot thus hold an “own IP address” and an “own program ID” that are needed in FIG. 15.

Thus, the reporter creator 610 extracts an IP address that is allocated to a device including the processor 50 being an object to be monitored that gives a report (hereafter, referred to as the IP address of a report processor) and a program ID to identify a program executed by the processor 50 (hereafter, referred to as a program ID of the report processor), and passes them to the node ID creator 604. In such a manner, the reporter creator 610 acquires reporting entity identification information to identify the processor 50 that gives a report of the data process. Here, the reporting entity identification information is, as an example, the couple of the IP address of a report processor and the program ID of the report processor.

The IP address of the report processor may be acquired by one of the receipt report acceptor 601, the conversion report acceptor 602, and the transmission report acceptor 603 from one of the processors 50-1 to 50-3 in response to the reception of a piece of report data, or may be transmitted by the processors 50-1 to 50-3 causing the IP addresses thereof to be contained in a piece of report data.

In addition, the program ID of the report processor may be estimated from a report processor IP address or the contents of a piece of report data, or may be transmitted by the processors 50-1 to 50-3 causing the program ID to identify a program executed by itself to be contained in a piece of report data.

In such a manner, in the remote BEMS (monitoring system) 1 in the second embodiment, the monitoring performer 6b includes the reporter creator 610 acquiring reporting entity identification information to identify the processor 50 that gives a report of the data process. Thereby, even in the case where one monitoring performer 6b monitors a plurality of programs 5, it is possible to extract start node IDs and end node IDs and to monitor the operation of the system as with the first embodiment.

### Third Embodiment

Next, a third embodiment will be described. In the first embodiment, the monitoring performer 6 creates a data flow edge based on an active report from the processor 50. However, the events of the data receiving and the data transmission by the processor 50 can often be externally detected, and in this case, the monitoring performer 6 does not need an active report from the processor 50. Thus, in the present embodiment, the monitoring performer 6 externally detects the communication of the processor 50 to create a data flow edge.

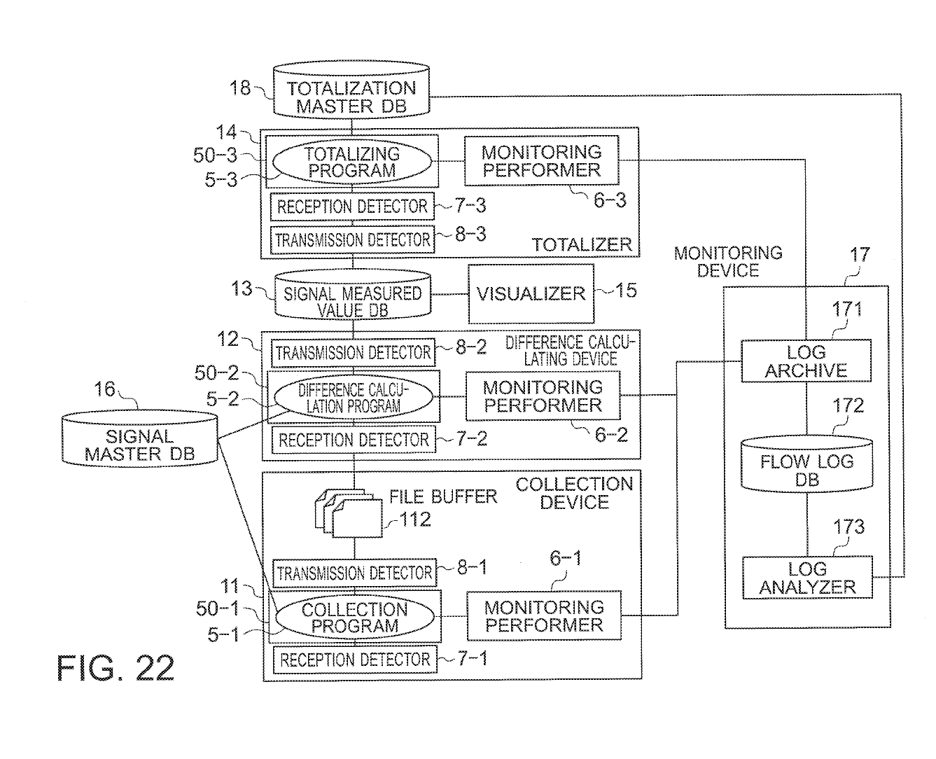

FIG. 22 is a diagram showing in detail the internal configuration of a remote BEMS 1 in the third embodiment.

As shown in FIG. 22, the configuration of the remote BEMS 1 in the third embodiment is a configuration, as compared with the detailed configuration of the remote BEMS 1 in the first embodiment shown in FIG. 3, in which reception detectors 7-1, 7-2, and 7-3 and transmission detectors 8-1, 8-2, and 8-3 are added.

The reception detector 7-1 is provided between the processor 50-1 and the network 3, and the transmission detector 8-1 is provided between the processor 50-1 and the file buffer 112. In addition, the reception detector 7-2 is provided between the processor 50-2 and the file buffer 112, and the transmission detector 8-2 is provided between the processor 50-2 and the signal measured value DB 13. In addition, the reception detector 7-3 and the transmission detector 8-3 are provided between the processor 50-3 and the signal measured value DB 13.

The reception detector 7-i, where i is an integer from one to three, detects all the pieces of data that are transferred to the processor 50-i, analyzes the contents thereof, and transmits pieces of report data to the receipt report acceptor 601 (to be described hereafter) of the monitoring performer 6. The pieces of report data transmitted by the reception detector 7-i are the same as the pieces of data transmitted by the data receiver 51 in the first embodiment (refer to FIG. 14). Hereafter, the reception detectors 7-1, 7-2, and 7-3 are collectively referred to as a reception detector 7.

The transmission detector 8-i detects all the pieces of data that are transferred from the processor 50-i, analyzes the contents thereof, and transmits pieces of report data to the transmission report acceptor 603 (to be described hereafter) of the monitoring performer 6. The pieces of report data transmitted by the transmission detector 8-i are the same as the pieces of data transmitted by the data transmitter 53 in the first embodiment (refer to FIG. 14). Hereafter, the transmission detectors 8-1, 8-2, and 8-3 are collectively referred to as a transmission detector 8.

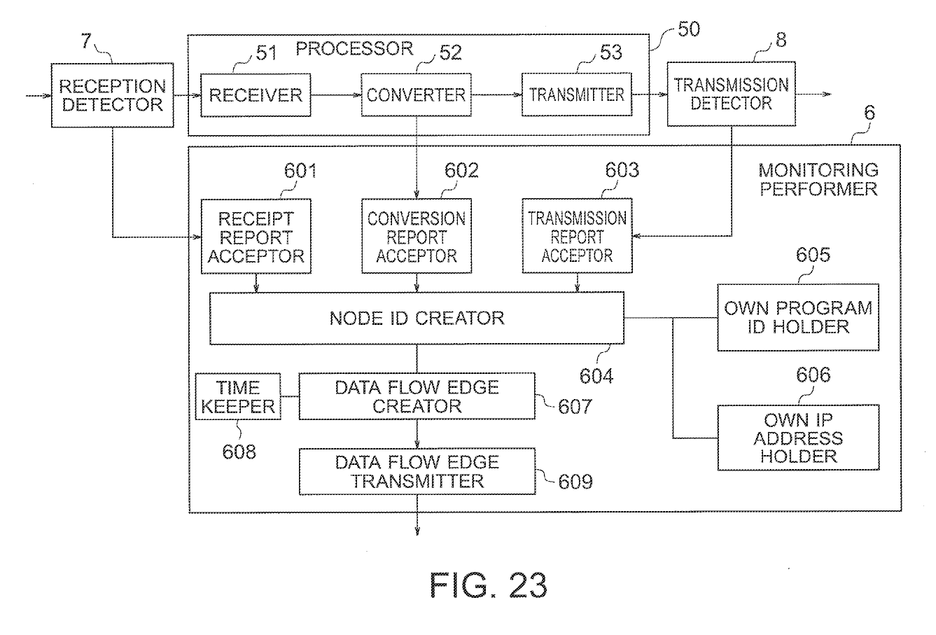

FIG. 23 is a diagram showing the configuration of the monitoring performer 6 in the third embodiment. This configuration is almost the same as the configuration of the monitoring performer 6 in the first embodiment shown in FIG. 11 except for that the receipt report acceptor 601 receives a report from the reception detector 7, and the transmission report acceptor 603 receives a report from the transmission detector 8.

To implement the present embodiment, the reception detector 7 or the transmission detector 8 must properly detect pieces of transferred data. The reception detector 7 or the transmission detector 8 may use one of first to fourth communication detecting methods as shown below.

A first detecting method is a method of using a packet capturing function provided by an OS (Operating System) to detect pieces of data that go in and out of the network interface of a device. This method is effective when the pieces of data are transferred between devices.

A second detecting method is a method of introducing a repeater in the network of a system, by which pieces of data flowing in the network is detected. This method is effective when the pieces of data are transferred between devices.

A third detecting method is a method of using a data detecting function of middleware that mediates data transfer, or altering the middleware to detect pieces of data.

A fourth detecting method is a method of detecting system calls of an OS used in data transfer.

In any method, if communication is not encrypted, it is possible to extract a signal ID and the like from detected contents of communication, and create a report data. Note that the reception detector 611 and the transmission detector 612 may be installed either in the same device as that of the processor 50 or in a device other than that of the processor 50 as long as they can detect communication.

As described above, in the third embodiment, the remote BEMS (monitoring system) 1 further includes the reception detector 7 detecting pieces of data input into receiver 51. Then, the monitoring performer 6 generates log information using the pieces of data detected by the reception detector 7. In addition, the remote BEMS (monitoring system) 1 further includes the transmission detector 8 detecting pieces of data output from the transmitter 53. The monitoring performer 6 generates log information using the pieces of data detected by the transmission detector 8.

According to the configuration of the remote BEMS (monitoring system) 1 in the third embodiment, it is possible to minimize the changes or alterations to the program 5 needed to implement system monitoring. In the case, in particular, of monitoring the processor 50-1 executing a program that does not convert data such as a collection program 5-1, the remote BEMS (monitoring system) 1 can perform the monitoring only by externally detecting data transfer.

### Fourth Embodiment

Next, a fourth embodiment will be described. In the first embodiment, the processors 50-1, 50-2, and 50-3 transfer pieces of data via data storages such as the file buffer 112 and the signal measured value DB 13. It is often the case where it is difficult to incorporate a monitoring function in an application level (e.g., a reporting function of a signal ID or a time stamp) into these data storages, and thus in the first embodiment, the monitoring of the whole data flow is implemented by monitoring the processor 50 handling the data storages.

However, if the monitoring function can be integrated into sequential functional elements that form the data flow, it is possible to reduce spots to be monitored or to monitor the time taken by the data transfer.

Thus, in the present embodiment, there will be described a method of system monitoring in the case where the processors 50-1 and 50-2 directly exchange pieces of data not via the file buffer 112.

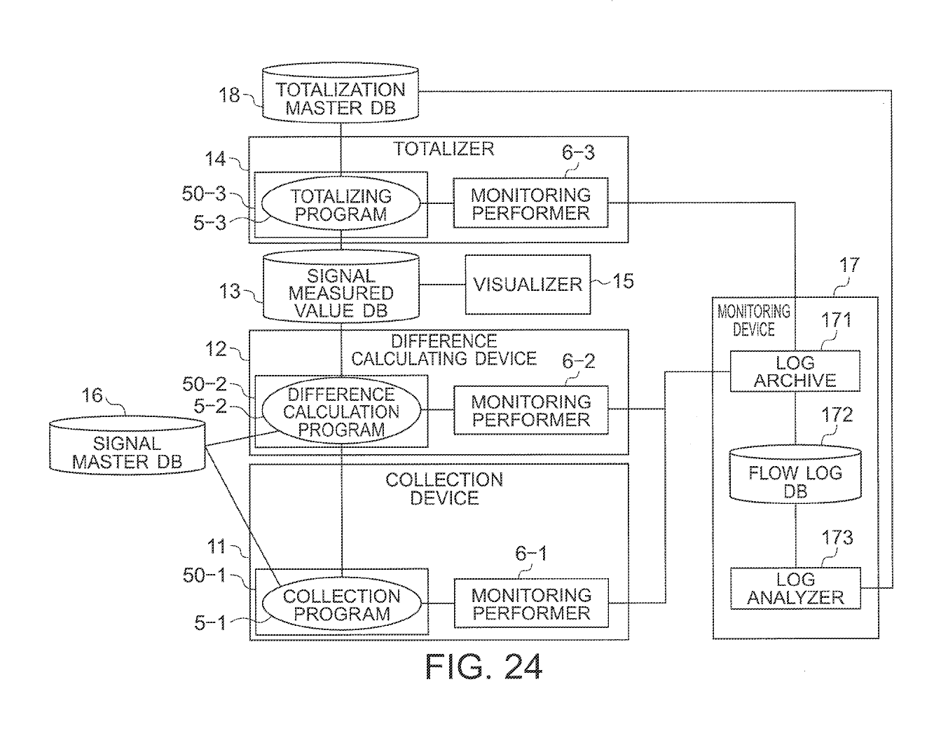

FIG. 24 is a diagram showing the internal configuration of a remote BEMS 1 in the fourth embodiment. The configuration of the remote BEMS 1 in the fourth embodiment is almost the same as the configuration of the remote BEMS 1 in the first embodiment shown in FIG. 3 except that the file buffer 112 does not exist.

In the present embodiment, the processor 50-1 transfers pieces of data collected from the buildings 2a and 2b to the processor 50-2 over a network in the system. The processor 50-2 performs a difference calculating process similar to that in the first embodiment on the pieces of data received in such a manner, and writes a difference calculation result into the signal measured value DB 13.

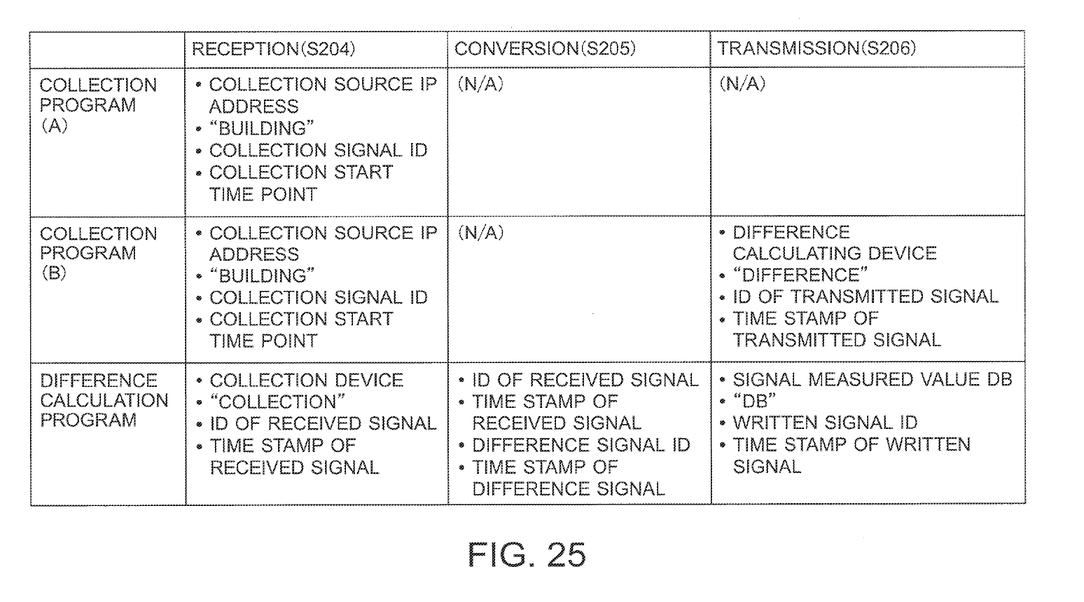

FIG. 25 is a diagram showing a specific example of kinds of report data in the fourth embodiment. In the present embodiment, there are two conceivable patterns of the report data by a collection program, and thus FIG. 25 shows both. Note that the kinds of report data from the processor 50-3 that executes a totalizing program is the same as those in the first embodiment.

In the present embodiment, as shown by case of collection program (A) in FIG. 25, the processor 50-1 executing the collection program can omit a report in transmitting. This is because the transfer of data can be reported using a reception event from the processor 50-2 executing the difference calculation program. In this case, for a creating rule of a node ID in the monitoring performer 6, the creating rule in the first embodiment (refer to FIG. 15) can be used as it is.

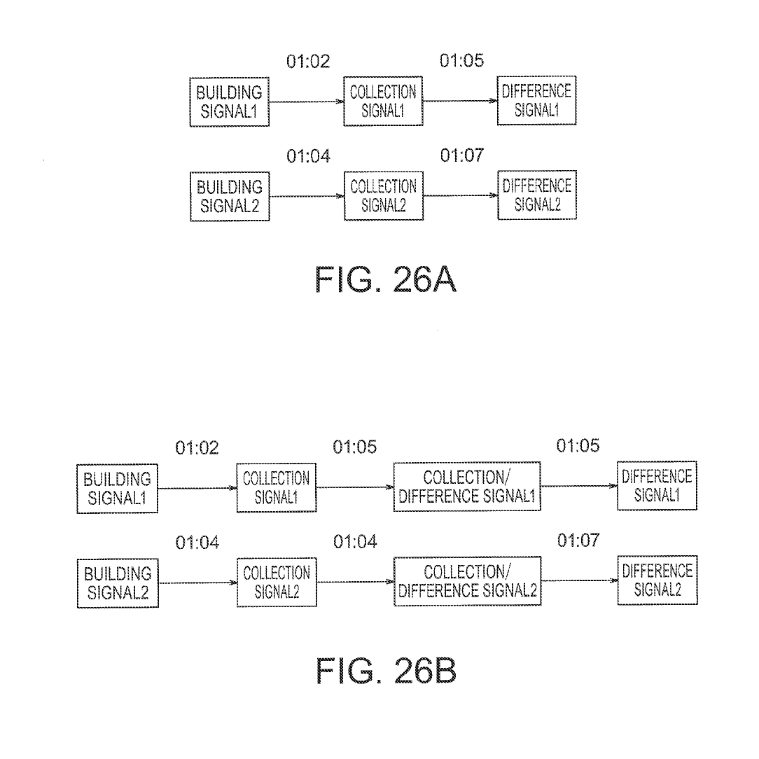

FIG. 26A is a diagram showing an example of a data flow in the case where the processor 50-1 does not make a transmission report. It is understood in comparison with FIG. 10 that, in this graph expression, a node corresponding to a “file” is eliminated from the graph in the first embodiment and a node of “collection” and a node of “difference” are directly connected to each other.

In such a manner, in the case where programs being an object to be monitored directly communicates with each other, a data flow can be recorded without problems only by recording reception events. Note that a similar data flow can also be recorded by recording only transmission events, it is desirable to record reception events because at the time of transmitting a piece of data, it is unknown in general whether the piece of data successfully reaches a transmission destination.

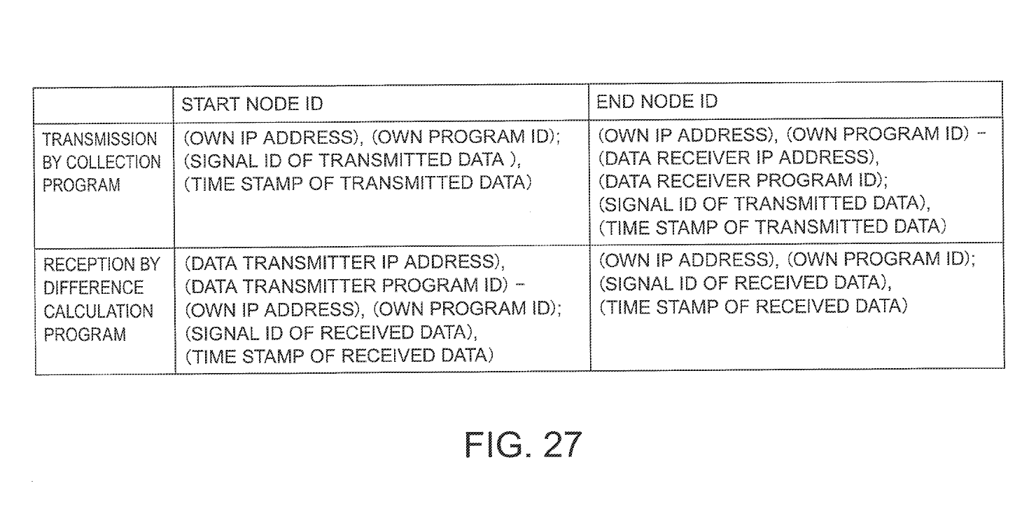

In contrast, as shown by case of collection program (B) in FIG. 25, also in the present embodiment, an event can be reported in both transmitting and receiving data. In this case, it is needed to alter node ID creating rules for the processor 50-1 executing the collection program 5-1 and the processor 50-2 executing the difference calculation program 5-2, as shown in FIG. 27.

FIG. 27 is a diagram showing a creating rule of a node ID for a transmission event of the processor 50-1 and a reception event of the processor 50-2 in the present embodiment. As shown in FIG. 27, in this case, assumed is a virtual node having a data handler ID “the IP address of the collection device 11, collection—the IP address of the difference calculating device 12, difference” (specifically, “192.168.0.11, collection-192.168.0.12, difference”) between the processor 50-1 and the processor 50-2. Then, a data flow is recorded assuming that pieces of data are transferred via this virtual node.

The monitoring performer 6 monitors the processor (first processor) 50-1 that transmits a piece of data and the processor (second processor) 50-2 that receives a piece of data using the node ID creating rule shown in FIG. 27. Specifically, the monitoring performer 6 generates log information containing a first identifier, a second identifier and a time point of the transmission whenever the processor (first processor) 50-1 transmits a piece of data to the processor (second processor) 50-2.

Here, the first identifier contains a data transmitting entity identifier to identify an entity that transmits a piece of data (in the example of FIG. 27, the couple of an own IP address and an own program ID) and a data identifier to identify the transmitted piece of data (in the example of FIG. 27, the couple of the signal ID of the piece of transmitted data and the time stamp of the piece of transmitted data).

The second identifier contains a data transmitting entity identifier to identify an entity that transmits a piece of data (in the example of FIG. 27, the couple of an own IP address and an own program ID) and a data receiving entity identifier to identify an entity that receives a piece of data (in the example of FIG. 27, the couple of a data receiver IP address and a data receiver program ID) and a data identifier to identify the transmitted piece of data (in the example of FIG. 27, the couple of the signal ID of a piece of transmitted data and the time stamp of the piece of transmitted data).

In addition, the monitoring performer 6 generates log information containing a third identifier, a fourth identifier, and a time point of the reception whenever the processor (second processor) 50-2 receives a piece of data from the processor (first processor) 50-1.

Here, the third identifier contains a data transmitting entity identifier to identify an entity that transmits a piece of data (in the example of FIG. 27, a data transmitter IP address and a data transmitter program ID), a data receiving entity identifier to identify an entity that receives a piece of data (in the example of FIG. 27, an own IP address and an own program ID), and a data identifier to identify the received piece of data (in the example of FIG. 27, the couple of the signal ID of a piece of received data and the time stamp of the piece of received data).

The fourth identifier contains a data receiving entity identifier to identify an entity that receives a piece of data (in the example of FIG. 27, the couple of an own IP address and an own program ID) and a data identifier to identify the received piece of data (in the case of FIG. 27, the couple of the signal ID of a piece of received data and the time stamp of the piece of received data).

FIG. 26B is a diagram showing an example of a data flow in the case where the processor 50-1 makes a transmission report.

FIG. 26A and FIG. 26B are records of the same data flow. From the observation of FIG. 26A, pieces of data of both a signal 1 and a signal 2 staying at “collection” nodes for three seconds are recorded. The stay times shown here include both a time for which the processor 50-1 that executes the collection program 5-1 holds a piece of data and a time taken for the piece of data to be transferred to the processor 50-2 that executes the difference calculation program 5-2.

In contrast, in the data flow shown in FIG. 26B, as to the signal 1, the processor 50-1 takes three seconds to hold a piece of data before transmitting the signal 1, and as to the signal 2, a transmission delay of three seconds is taken from the transmission by the processor 50-1 to the reception by the processor 50-2.

In such a manner, by assuming a virtual intermediate node at the time of recording data transfer events, it is possible to record times taken by data transfer itself.

As described above, in the remote BEMS (monitoring system) 1 in the fourth embodiment, the monitoring performer 6 monitors the processor (first processor) 50-1 transmitting a piece of data, the processor (second processor) 50-2 receiving the piece of data, whenever the processor (first processor) 50-1 transmits a piece of data to the processor (second processor) 50-2, generates log information containing a first identifier, a second identifier, and a time point of the transmission, and whenever the processor (second processor) 50-2 receives the piece of data from the processor (first processor) 50-1, generates log information containing a third identifier, a fourth identifier, and a time point of the reception.

As described above, in the case of monitoring both processors adjacent to each other on a data flow, by assuming a virtual intermediate node at the time of recording data transfer events, it is possible to evaluate a transmission delay.

In addition, in the present embodiment, delivering pieces of data between the processor 50-1 and the processor 50-2 is configured to directly transfer the pieces of data from the processor 50-1 to the processor 50-2 without using a file buffer, and thus it is possible to reduce events to be monitored as compared with the first embodiment.

In addition, the abovementioned various processes according to the monitoring performers 6 and 6b and/or the monitoring device 17 in the embodiments may be performed by recording a program for executing the processes of the monitoring performers 6 and 6b and/or the monitoring device 17 in the embodiments in a computer-readable recording medium, causing a computer system to read the program recorded in the recording medium, and causing a processor to execute the program.

The terms used in each embodiment should be interpreted broadly. For example, the term “processor” may encompass a general purpose processor, a central processor (CPU), a microprocessor, a digital signal processor (DSP), a controller, a microcontroller, a state machine, and so on. According to circumstances, a “processor” may refer to an application specific integrated circuit (ASIC), a field programmable gate array (FPGA), and a programmable logic device (PLD), etc. The term “processor” may refer to a combination of processing devices such as a plurality of microprocessors, a combination of a DSP and a microprocessor, one or more microprocessors in conjunction with a DSP core.

As another example, the term “memory” may encompass any electronic component which can store electronic information. The “memory” may refer to various types of media such as random access memory (RAM), read-only memory (ROM), programmable read-only memory (PROM), erasable programmable read only memory (EPROM), electrically erasable PROM (EEPROM), non-volatile random access memory (NVRAM), flash memory, magnetic or optical data storage, which are readable by a processor. It can be said that the memory electronically communicates with a processor if the processor read and/or write information for the memory. The memory may be integrated to a processor and also in this case, it can be said that the memory electronically communication with the processor.

The term “storage” or “storage device” may generally encompass any device which can memorize data permanently by utilizing magnetic technology, optical technology or non-volatile memory such as an HDD, an optical disc or SSD.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A monitoring system that monitors a data process using log information, comprising:
a first circuitry to convert a piece of data under a predetermined rule; and
a second circuitry to, when the piece of data is converted by the first circuitry, generates first log information that contains start node identification information, end node identification information and a process executing time point wherein the start node identification information contains information to identify a piece of data before the conversion, the end node identification information contains information to identify a piece of data after the conversion, and the process executing time point is a time point at which the piece of data is converted.

2. The monitoring system according to claim 1, wherein the start node identification information and the end node identification information contained in the first log information each further contain information to identify an entity that converts the piece of data.

3. The monitoring system according to claim 1, further comprising
a third circuitry to receive a piece of data, wherein
when the piece of data is received by the third circuitry, the second circuitry generates second log information that contains start node identification information, end node identification information, a process executing time point wherein the start node identification information contains information to identify a transmission source of the received piece of data, the end node identification information containing information to identify an entity that receives the piece of data, and the process executing time point is a time point at which the piece of data is received.

4. The monitoring system according to claim 3, wherein the start node identification information and the end node identification information contained in the second log information each further contain information to identify the received piece of data.

5. The monitoring system according to claim 1, further comprising
a fourth circuitry to transmit a piece of data, wherein
when the piece of data is transmitted by the fourth circuitry, the second circuitry generates third log information that contains start node identification information, end node identification information and a process executing time point wherein the start node identification information contains information to identify an entity that transmits the piece of data, the end node identification information contains information to identify a transmission destination of the transmitted piece of data, and the process executing time point is a time point at which the piece of data is transmitted.

6. The monitoring system according to claim 5, wherein the start node identification information and the end node identification information contained in the third log information each further contain information to identify the transmitted piece of data.

7. The monitoring system according to claim 5, further comprising a log archive that stores at least one of the log information, the second log information, and the third log information in a storage device.

8. The monitoring system according to claim 7, further comprising:
a fifth circuitry to, when a current time reaches a predetermined deadline time point, for each piece of data a process of which needs to be completed by the deadline time point, judge whether the end node identification information contains information to identify the piece of data and whether log information having the process executing time point being a time point before the deadline time point is stored in the storage device; and
a sixth circuitry to, for at least one of the pieces of data, perform a process of notifying a deadline violation in a case where the fifth circuitry judges that log information in which the end node identification information contains information to identify the piece of data and the process executing time point is a time point before the deadline time point is not stored in the storage device.

9. The monitoring system according to claim 7, further comprising a bottleneck analyzer to specify a couple of pieces of log information among a set of pieces of log information stored in the storage device wherein one log information in the couple of pieces of log information includes the end node identification information and the other log information includes the start node identification information identical to the end node identification information,
calculate a difference between a process executing time point contained in the one log information and a process executing time point contained in the other log information wherein the difference represents a stay time of a piece of data that is identified by the end node identification information or the start node identification, and
identify a data process which is a bottleneck using the difference.

10. The monitoring system according to claim 3, wherein the second circuitry acquires data receipt report information from the third circuitry when a piece of data is received by the third circuitry and generates the second log information each time the data receipt report information is acquired, the data receipt report information containing information to identify a transmission source of the received piece of data and information to identify the received piece of data.

11. The monitoring system according to claim 1, wherein
the second circuitry acquires data conversion report information from the first circuitry when a piece of data is converted by the first circuitry and generates the log information whenever the data conversion report information is acquired, the data conversion report information containing information to identify the piece of data before the conversion and information to identify the piece of data after the conversion.

12. The monitoring system according to claim 5, wherein the second circuitry acquires data transmission report information from the fourth circuitry when a piece of data is transmitted by the fourth circuitry and generates the third log information each time the data transmission report information is acquired, the data transmission report information containing information to identify a transmission destination of the transmitted piece of data and information to identify the transmitted piece of data.

13. The monitoring system according to claim 3, further comprising
a seventh circuitry to detect a piece of data input into the third circuitry, wherein
the second circuitry generates the second log information using the piece of data detected by the seventh circuitry.

14. The monitoring system according to claim 5, further comprising
an eighth circuitry to detect a piece of data output from the fourth circuitry, wherein
the second circuitry generates the third log information using the piece of data detected by the eighth circuitry.

15. The monitoring system according to claim 1, wherein
the second circuitry monitors a first processor that transmits a piece of data and a second processor that receives the piece of data, generates log information that contains a first identifier, a second identifier, and a time point of the transmission each time the first processor transmits a piece of data to the second processor, and generates log information that contains a third identifier, a fourth identifier, and a time point of the reception each time the second processor receives a piece of data from the first processor,
the first identifier contains a data transmitting entity identifier to identify an entity that transmits the piece of data and a data identifier to identify the transmitted piece of data,
the second identifier contains a data transmitting entity identifier to identify an entity that transmits the piece of data, a data receiving entity identifier to identify an entity that receives the piece of data, and a data identifier to identify the transmitted piece of data,
the third identifier contains a data transmitting entity identifier to identify an entity that transmits the piece of data, a data receiving entity identifier to identify an entity that receives the piece of data, and a data identifier to identify the received piece of data, and
the fourth identifier contains a data receiving entity identifier to identify an entity that receives the piece of data and a data identifier to identify the received piece of data.

16. A monitoring device that monitors a data process using log information, comprising:
circuitry to, when a piece of data is converted by a converter, generates log information that contains start node identification information, end node identification information and a process executing time point wherein the start node identification information contains information to identify a piece of data before the conversion, the end node identification information contains information to identify a piece of data after the conversion, and the process executing time point is a time point at which the piece of data is converted.

17. A monitoring method of a data process using log information, the method being performed by a computer, the method comprising:
generating, when a piece of data is converted by a converter, log information that contains start node identification information, end node identification information and a process executing time point wherein the start node identification information contains information to identify a piece of data before the conversion, the end node identification information contains information to identify a piece of data after the conversion, and the process executing time point is a time point at which the piece of data is converted.

18. A monitoring system that monitors a data process using log information, comprising:
a first circuitry to receive a piece of data; and
a second circuitry to, when a piece of data is received by the first circuitry, generates log information that contains start node identification information, end node identification information and a process executing time point wherein the start node identification information contains information to identify a transmission source of the received piece of data, the end node identification information contains information to identify an entity that receives the piece of data, and the process executing time point is a time point at which the piece of data is received.
